(19) United States
(12) Patent Application Publication
(10) Pub. No.: US 2026/0362769 A1
(43) Pub. Date: Nov. 12, 2026

(54) SEMICONDUCTOR DEVICE INCLUDING BACK WELL

(71) Applicant: Samsung Electronics Co., Ltd., Suwon-si (KR)

(72) Inventors: Cheonbae KIM, Suwon-si (KR); Sunhae SHIN, Suwon-si (KR); Woochoel NOH, Suwon-si (KR); Joon HAN, Suwon-si (KR)

(73) Assignee: Samsung Electronics Co., Ltd., Suwon-si (KR)

(21) Appl. No.: 19/665,418

(22) Filed: May 1, 2026

(30) Foreign Application Priority Data
May 8, 2025 (KR) 10-2025-0059912

(51) Int. Cl. H10D 62/60; H10B 12/00; H10B 80/00; H10D 30/01; H10D 62/10; H10D 80/30; H10W 90/00

(52) U.S. Cl. CPC H10D 62/60; H10B 12/315; H10B 12/482; H10B 12/488; H10D 62/124; H10B 80/00; H10D 30/027; H10D 80/30; H10W 90/792

(57) ABSTRACT

A semiconductor device that includes a cell array structure including a plurality of cells; and a peripheral circuit structure on the cell array structure, the peripheral circuit structure including a peripheral circuit substrate having a peripheral circuit active surface and a peripheral circuit inactive surface opposite to each other. The peripheral circuit substrate includes a front P-well and a front N-well each extending from the peripheral circuit active surface into the peripheral circuit substrate, and a back P-well extending from the peripheral circuit inactive surface into the peripheral circuit substrate and overlapping the front P-well in a vertical direction. A doping profile of the back P-well decreases toward the peripheral circuit active surface from a peak of a dopant concentration of the back P-well that is adjacent to the peripheral circuit inactive surface and that is spaced apart from the peripheral circuit inactive surface in the vertical direction.

### CROSS-REFERENCE TO RELATED APPLICATION

This application is based on and claims priority under 35 U.S.C. § 119 to Korean Patent Application No. 10-2025-0059912, filed on May 8, 2025, in the Korean Intellectual Property Office, the disclosure of which is incorporated by reference herein in its entirety.

### BACKGROUND

The inventive concepts relate to semiconductor devices. More particularly, the inventive concepts relate to semiconductor devices in which a cell array structure and a peripheral circuit structure overlap each other in a vertical direction.

With demand for high integration of semiconductor devices, a semiconductor device in which a cell array structure and a peripheral circuit structure overlap each other in a vertical direction has been developed.

### SUMMARY

Some example embodiments of the inventive concepts provide a highly-integrated semiconductor device having improved operational reliability.

Some example embodiments of the inventive concepts provide a semiconductor device that includes a cell array structure including a plurality of cells; and a peripheral circuit structure on the cell array structure, the peripheral circuit structure including a peripheral circuit substrate having a peripheral circuit active surface and a peripheral circuit inactive surface opposite to each other. The peripheral circuit substrate includes a front P-well and a front N-well each extending from the peripheral circuit active surface into the peripheral circuit substrate, and a back P-well extending from the peripheral circuit inactive surface into the peripheral circuit substrate and overlapping the front P-well in a vertical direction. A doping profile of the back P-well decreases toward the peripheral circuit active surface from a peak of a dopant concentration of the back P-well that is adjacent to the peripheral circuit inactive surface and that is spaced apart from the peripheral circuit inactive surface in the vertical direction.

Some example embodiments of the inventive concepts further provide a semiconductor device that includes a cell array structure including a plurality of memory cells including a plurality of semiconductor patterns, a plurality of word lines adjacent to the plurality of semiconductor patterns, a plurality of bit lines connected to the plurality of semiconductor patterns, and a plurality of information storage elements connected to the plurality of semiconductor patterns; a peripheral circuit structure including a peripheral circuit substrate having a peripheral circuit active surface and a peripheral circuit inactive surface opposite to each other, and a plurality of peripheral circuit transistors along the peripheral circuit active surface, the peripheral circuit substrate being stacked on the cell array structure; and a bonding structure between the cell array structure and the peripheral circuit structure, the bonding structure bonding the cell array structure to the peripheral circuit structure. The peripheral circuit substrate includes a front P-well and a front N-well each extending from the peripheral circuit active surface into the peripheral circuit substrate, and a back P-well and a back N-well each extending from the peripheral circuit inactive surface into the peripheral circuit substrate. A doping profile of the back P-well decreases toward the peripheral circuit active surface from a peak of dopant concentration of the back P-well, the peak of the dopant concentration of the back P-well being adjacent to and spaced apart from the peripheral circuit inactive surface in a vertical direction. A doping profile of the back N-well decreases toward the peripheral circuit active surface from a peak of a dopant concentration of the back N-well, the peak of the dopant concentration of the back N-well being adjacent to and spaced apart from the peripheral circuit inactive surface in the vertical direction.

Some example embodiments of the inventive concepts still further provide a semiconductor device that includes a cell array structure including a plurality of bit lines each extending in a first horizontal direction, a plurality of contact plugs each extending in a vertical direction, a plurality of channel patterns each extending in the vertical direction between the plurality of bit lines and respective first ends of the plurality of contact plugs, a plurality of word lines and a plurality of back gate electrodes each extending in a second horizontal direction orthogonal to the first horizontal direction and between the plurality of bit lines and the respective first ends of the plurality of contact plugs, the plurality of word lines and the plurality of back gate electrodes being spaced apart from each other with the plurality of channel patterns between the plurality of word lines and the plurality of back gate electrodes, and a plurality of capacitors including a plurality of lower electrodes connected to respective other ends of the plurality of contact plugs, a capacitor dielectric layer covering the plurality of lower electrodes, and an upper electrode covering the capacitor dielectric layer; a peripheral circuit structure including a peripheral circuit substrate having a peripheral circuit active surface and a peripheral circuit inactive surface opposite to each other, and a plurality of peripheral circuit transistors along the peripheral circuit active surface, the peripheral circuit substrate being stacked on the cell array structure; and a bonding structure between the cell array structure and the peripheral circuit structure, the bonding structure configured to bond the cell array structure to the peripheral circuit structure. The peripheral circuit substrate includes a front P-well and a front N-well each extending from the peripheral circuit active surface into the peripheral circuit substrate, a back P-well extending from the peripheral circuit inactive surface into the peripheral circuit substrate and overlapping the front P-well in the vertical direction, and a back N-well extending from the peripheral circuit inactive surface into the peripheral circuit substrate and overlapping the front N-well in the vertical direction. A doping profile of the back P-well decreases toward the peripheral circuit active surface from a peak of dopant concentration of the back P-well, the peak of the dopant concentration of the back P-well being adjacent to and spaced apart from the peripheral circuit inactive surface in the vertical direction. A doping profile of the back N-well decreases toward the peripheral circuit active surface from a peak of a dopant concentration of the back N-well, the peak of the dopant concentration of the back N-well being adjacent to and spaced apart from the peripheral circuit inactive surface in the vertical direction.

### BRIEF DESCRIPTION OF THE DRAWINGS

Some example embodiments will be more clearly understood from the following detailed description taken in conjunction with the accompanying drawings in which:

FIG. 1 is a schematic cross-sectional view of a semiconductor device according to some example embodiments;

FIG. 2 is a schematic cross-sectional view of a semiconductor device according to some example embodiments;

FIGS. 3, 4, 5A, 6, 7, 8, 9, 10A, and 11A are cross-sectional views illustrating a method of manufacturing a peripheral circuit structure included in a semiconductor device according to some example embodiments, and FIGS. 5B, 10B, and 11B are graphs showing doping profiles of a peripheral circuit substrate included in the peripheral circuit structure;

FIGS. 12A, 13A, and 14A are cross-sectional views illustrating a method of manufacturing a peripheral circuit structure included in a semiconductor device according to some example embodiments, and FIGS. 12B, 13B, and 14B are graphs showing doping profiles of a peripheral circuit substrate included in the peripheral circuit structure;

FIGS. 15A, 15B, 16A, 16B, and 16C are cross-sectional views illustrating a method of manufacturing a peripheral circuit structure included in a semiconductor device according to some example embodiments;

FIG. 17 is a perspective view for illustrating a method of manufacturing a semiconductor device, according to some example embodiments;

FIG. 18 is a block diagram of a semiconductor device according to some example embodiments;

FIG. 19 is a schematic perspective view of a semiconductor device according to some example embodiments;

FIGS. 20 and 21 are cross-sectional views of semiconductor devices according to some example embodiments;

FIG. 22 is a schematic perspective view of a semiconductor device according to some example embodiments; and

FIGS. 23 and 24 are cross-sectional views of semiconductor devices according to some example embodiments.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

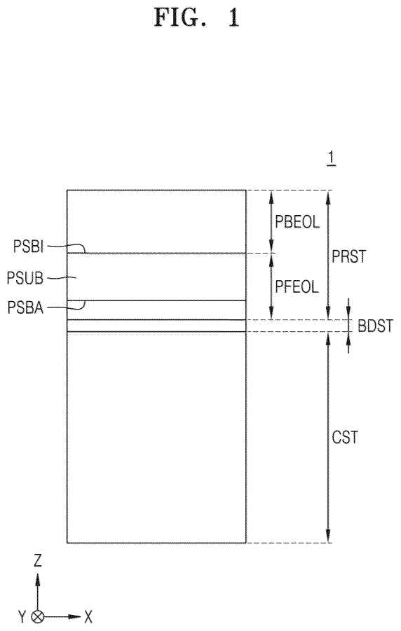

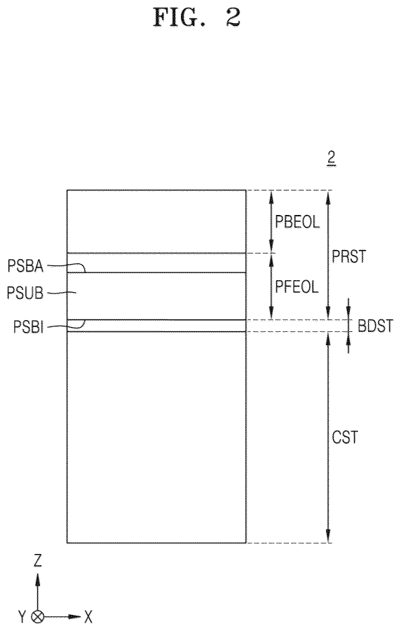

FIG. 1 is a schematic cross-sectional view of a semiconductor device 1 according to some example embodiments.

Referring to FIG. 1, the semiconductor device 1 includes a cell array structure CST and a peripheral circuit structure PRST overlapping each other in a vertical direction (e.g., a Z direction). The semiconductor device 1 may have a Periphery on Cell (PoC) structure in which the peripheral circuit structure PRST is disposed over the cell array structure CST.

A plurality of cells may be arranged in the cell array structure CST. According to some example embodiments, the semiconductor device 1 may be a semiconductor memory device in which a plurality of memory cells are arranged in the cell array structure CST. For example, the semiconductor device 1 may be a semiconductor memory device including a plurality of dynamic random access memory (DRAM) cells, a plurality of vertical channel transistor DRAM cells, a plurality of 3D DRAM cells, a plurality of flash memory cells, a plurality of NAND memory cells, a plurality of vertical NAND (VNAND) memory cells, a plurality of phase-change random access memory (PRAM) cells, a plurality of magnetic random access memory (MRAM) cells, or a plurality of resistive random access memory (RRAM) cells in a cell array structure CST. According to some example embodiments, the semiconductor device 1 may be an image sensor device in which a plurality of image sensor cells are arranged in a cell array structure CST. For example, the semiconductor device 1 may include a CMOS image sensor (CIS).

The peripheral circuit structure PRST includes a peripheral circuit device layer PFEOL and a peripheral circuit wiring layer PBEOL on the peripheral circuit device layer PFEOL. The peripheral circuit device layer PFEOL includes a peripheral circuit substrate PSUB in which a plurality of peripheral circuit transistors are formed.

For example, the peripheral circuit substrate PSUB may include a semiconductor material such as a Group IV semiconductor material, a Groups III and V semiconductor material, a Groups II and VI semiconductor material, or a Groups II and VI oxide semiconductor material. A plurality of peripheral circuit transistors included in the peripheral circuit structure PRST may be configured to transmit signals and/or power to the cell array structure CST. For example, the plurality of peripheral circuit transistors included in the peripheral circuit structure PRST may form various circuits such as a command decoder, a control logic, an address buffer, a row decoder, a column decoder, a sense amplifier, and a data input/output circuit.

The peripheral circuit substrate PSUB may have a peripheral circuit active surface PSBA and a peripheral circuit inactive surface PSBI that are opposite to each other. The peripheral circuit active surface PSBA may be referred to as a front surface, and the peripheral circuit inactive surface PSBI may be referred to as a back surface of the peripheral circuit substrate PSUB. Each of the peripheral circuit active surface PSBA and the peripheral circuit inactive surface PSBI may extend in a first horizontal direction (X direction) and a second horizontal direction (Y direction). The first horizontal direction (X direction) and the second horizontal direction (Y direction) may be orthogonal to each other. The plurality of peripheral circuit transistors may be arranged along the peripheral circuit active surface PSBA. According to some example embodiments, the peripheral circuit active surface PSBA may face the cell array structure CST, and the peripheral circuit inactive surface PSBI may face the peripheral circuit wiring layer PBEOL. The peripheral circuit wiring layer PBEOL may be electrically connected to the plurality of peripheral circuit transistors included in the peripheral circuit structure PRST and/or a plurality of cells included in the cell array structure CST, or may electrically connect the plurality of peripheral circuit transistors included in the peripheral circuit structure PRST to the plurality of cells included in the cell array structure CST.

The semiconductor device 1 may include a bonding structure BDST interposed between the cell array structure CST and the peripheral circuit structure PRST. The cell array structure CST and the peripheral circuit structure PRST may be electrically connected to each other via the bonding structure BDST. According to some example embodiments, the semiconductor device 1 may include the cell array structure CST, the bonding structure BDST, the peripheral circuit device layer PFEOL of the peripheral circuit structure PRST, and the peripheral circuit wiring layer PBEOL of the peripheral circuit structure PRST that are sequentially arranged in the vertical direction (Z direction). The cell array structure CST, the peripheral circuit structure PRST, and the bonding structure BDST may be arbitrarily distinguished from one another based on convenience of explanation and functional differences, and thus the distinction between them may not be clear. For example, some of the components included in the bonding structure BDST may be formed to extend from the bonding structure BDST into the cell array structure CST and/or the peripheral circuit structure PRST.

According to some example embodiments, after a first wafer including a plurality of cell array structures CST is formed, a second wafer including at least some of a plurality of peripheral circuit structures PRST may be bonded onto the first wafer such that the peripheral circuit active surface PSBA faces the first wafer, and the stacked structure of the first wafer and the second wafer may be diced to thereby form a plurality of semiconductor devices 1 each including the cell array structure CST and the peripheral circuit structure PRST corresponding to each other.

According to some example embodiments, after the second wafer including at least some of the plurality of peripheral circuit structures PRST may be bonded onto the first wafer including the plurality of cell array structures CST, the rest of the plurality of peripheral circuit structures PRST may be formed on the stacked structure of the first wafer and the second wafer, and then the stacked structure of the first wafer and the second wafer may be diced to thereby form a plurality of semiconductor devices 1 each including the cell array structure CST and the peripheral circuit structure PRST corresponding to each other. For example, each of the some of the plurality of peripheral circuit structures PRST may be the peripheral circuit device layer PFEOL, and each of the rest of the plurality of peripheral circuit structures PRST may be the peripheral circuit wiring layer PBEOL.

A first portion of the bonding structure BDST may be formed on the first wafer, a second portion of the bonding structure BDST may be formed on the second wafer, the second wafer may be bonded onto the first wafer, and then the first portion of the bonding structure BDST and the second portion of the bonding structure BDST may form the bonding structure BDST

FIG. 2 is a schematic cross-sectional view of a semiconductor device 2 according to some example embodiments.

Referring to FIG. 2, the semiconductor device 2 includes a cell array structure CST and a peripheral circuit structure PRST overlapping each other in the vertical direction (e.g., the Z direction). The semiconductor device 2 may have a PoC structure in which the peripheral circuit structure PRST is disposed over the cell array structure CST.

The peripheral circuit structure PRST includes a peripheral circuit device layer PFEOL and a peripheral circuit wiring layer PBEOL on the peripheral circuit device layer PFEOL. The peripheral circuit device layer PFEOL includes a peripheral circuit substrate PSUB in which a plurality of peripheral circuit transistors are formed. The peripheral circuit substrate PSUB may have a peripheral circuit active surface PSBA and a peripheral circuit inactive surface PSBI that are opposite to each other. According to some example embodiments, the peripheral circuit active surface PSBA may face the peripheral circuit wiring layer PBEOL, and the peripheral circuit inactive surface PSBI may face the cell array structure CST.

The semiconductor device 2 may include a bonding structure BDST interposed between the cell array structure CST and the peripheral circuit structure PRST. According to some example embodiments, the semiconductor device 2 may include the cell array structure CST, the bonding structure BDST, the peripheral circuit device layer PFEOL of the peripheral circuit structure PRST, and the peripheral circuit wiring layer PBEOL of the peripheral circuit structure PRST that are sequentially arranged in the vertical direction (Z direction). For example, the bonding structure BDST may be formed to cover the peripheral circuit inactive surface PSBI.

According to some example embodiments, after a first wafer including a plurality of cell array structures CST is formed, a second wafer including at least some of a plurality of peripheral circuit structures PRST may be bonded onto the first wafer such that the peripheral circuit inactive surface PSBI faces the first wafer, and the stacked structure of the first wafer and the second wafer may be diced to thereby form a plurality of semiconductor devices 2 each including the cell array structure CST and the peripheral circuit structure PRST corresponding to each other.

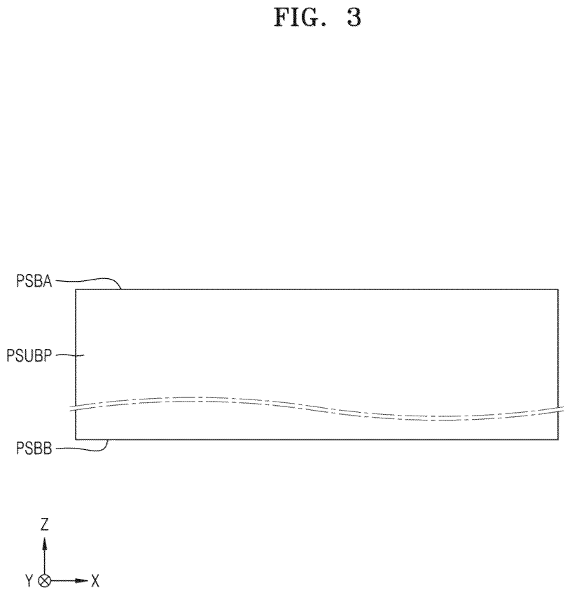

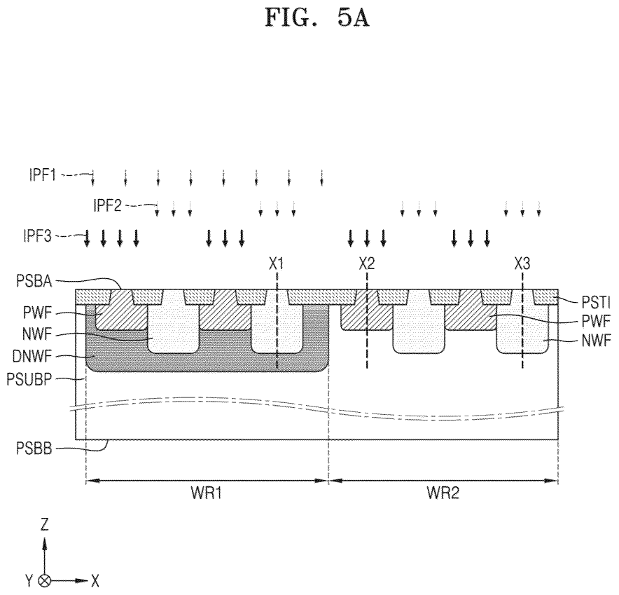

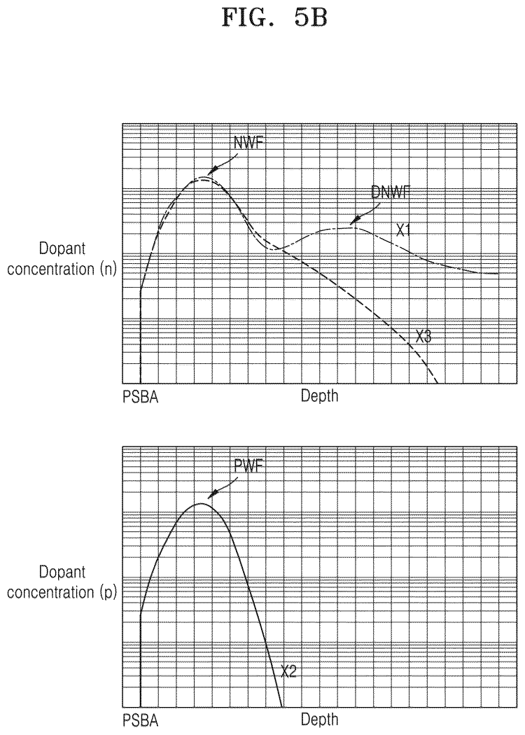

FIGS. 3, 4, 5A, 6, 7, 8, 9, 10A, and 11A are cross-sectional views illustrating a method of manufacturing a peripheral circuit structure included in a semiconductor device according to some example embodiments, and FIGS. 5B, 10B, and 11B are graphs showing doping profiles of a peripheral circuit substrate included in the peripheral circuit structure.

Referring to FIG. 3, a preliminary peripheral circuit substrate PSUBP having a peripheral circuit active surface PSBA and a preliminary peripheral circuit inactive surface PSBB that are opposite to each other is prepared. The preliminary peripheral circuit substrate PSUBP may include, for example, a semiconductor material such as a Group IV se miconductor material, a Groups III and V semiconductor material, a Groups II and VI semiconductor material, or a Groups II and VI oxide semiconductor material. The Group IV semiconductor material may include, for example, silicon (Si), germanium (Ge), or Si-Ge. The Groups III and V semiconductor material may include, for example, gallium arsenide (GaAs), indium phosphorus (InP), gallium phosphorus (GaP), indium arsenide (InAs), indium antimony (InSb), or indium gallium arsenide (InGaAs). The Groups II and VI semiconductor material may include, for example, zinc telluride (ZnTe) or cadmium sulfide (CdS). The preliminary peripheral circuit substrate PSUBP may be a bulky wafer or an epitaxial layer. The preliminary peripheral circuit substrate PSUBP may be provided as a bulky wafer or an epitaxial layer. According to some example embodiments, the preliminary peripheral circuit substrate PSUBP may be a p-type wafer formed by injecting p-type impurities.

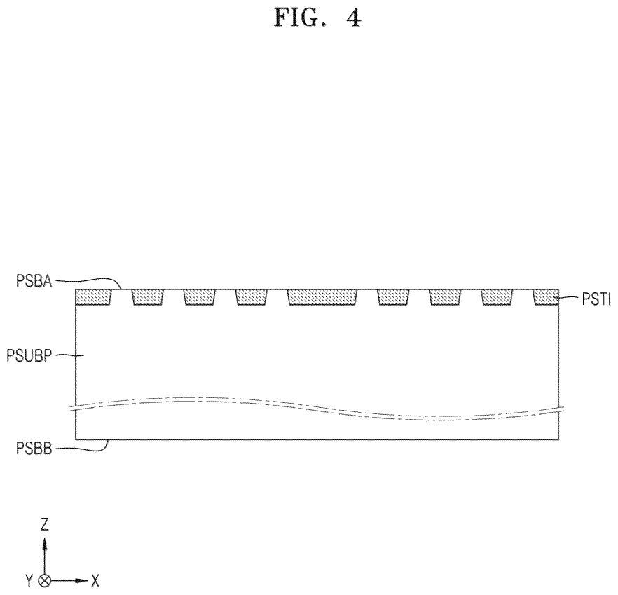

Referring to FIG. 4, after a portion of the preliminary peripheral circuit substrate PSUBP is removed, a circuit device isolation layer PSTI is formed to fill a space from which a portion of the preliminary peripheral circuit substrate PSUBP has been removed. For example, the circuit device isolation layer PSTI may be formed to fill a space created by removing a portion of the preliminary peripheral circuit substrate PSUBP from the peripheral circuit active surface PSBA. Portions of the preliminary peripheral circuit substrate PSUBP defined by the circuit device isolation layer PSTI may be referred to as a plurality of active regions. For example, the plurality of active regions may be portions of the preliminary peripheral circuit substrate PSUBP that are defined by the circuit device isolation layer PSTI and are adjacent to the peripheral circuit active surface PSBA. The circuit device isolation layer PSTI may include, for example, a material including at least one of silicon oxide, silicon nitride, and silicon oxynitride. The circuit device isolation layer PSTI may be a single layer including one type of insulation layer, a dual layer including two types of insulation layers, or a multi-layer including at least three types of insulation layers. For example, the circuit device isolation layer PSTI may be a dual layer or multi-layer including an oxide layer and a nitride layer. However, some example embodiments are not limited to the above-described structure of the circuit device isolation layer PSTI.

Referring to FIGS. 5A and 5B, ion implantation may be performed through the peripheral circuit active surface PSBA of the preliminary peripheral circuit substrate PSUBP to form front P-wells PWF, front N-wells NWF, and deep front N-well DNWF. Each of the front P-wells PWF, the front N-wells NWF, and the deep front N-well DNWF may be formed to extend from the peripheral circuit active surface PSBA into the preliminary peripheral circuit substrate PSUBP. The deep front N-well DNWF may be formed by implanting n-type impurities into a portion of the preliminary peripheral circuit substrate PSUBP adjacent to the peripheral circuit active surface PSBA via a first ion implantation IPF1, the front N-wells NWF may be formed by implanting n-type impurities into a portion of the preliminary peripheral circuit substrate PSUBP adjacent to the peripheral circuit active surface PSBA via a second ion implantation IPF2, and the front P-wells PWF may be formed by implanting p-type impurities into a portion of the preliminary peripheral circuit substrate PSUBP adjacent to the peripheral circuit active surface PSBA via a third ion implantation IPF3. The front P-wells PWF may be spaced apart from each other, and the front N-wells NWF may be spaced apart from each other.

According to some example embodiments, the second ion implantation IPF2 and the third ion implantation IPF3 may be performed sequentially after the first ion implantation IPF1 is performed. However, the order of performing the first ion implantation IPF1, the second ion implantation IPF2, and the third ion implantation IPF3 is not limited thereto. The first ion implantation IPF1 may be referred to as a first front ion implantation, the second ion implantation IPF2 may be referred to as a second front ion implantation, and the third ion implantation IPF3 may be referred to as a third front ion implantation. According to some example embodiments, the first ion implantation IPF1 may not be performed so that the deep front N-well DNWF is not formed in the preliminary peripheral circuit substrate PSUBP.

FIG. 5B shows a doping profile measured according to depths from the peripheral circuit active surface PSBA toward the interior of the preliminary peripheral circuit substrate PSUBP along X1, X2, and X3 of FIG. 5A. A peak of a dopant concentration of the front N-well NWF may be located at a portion of the preliminary peripheral circuit substrate PSUBP adjacent to the peripheral circuit active surface PSBA but spaced apart from the peripheral circuit active surface PSBA in a depth direction, e.g., in the vertical direction. A peak of a dopant concentration of the front N-well NWF may be formed at a less depth from the peripheral circuit active surface PSBA than a peak of a dopant concentration of the deep front N-well DNWF. A value of the peak of the dopant concentration of the front N-well NWF may be formed to be greater than a value of the peak of the dopant concentration of the deep front N-well DNWF. The peak of the dopant concentration of the front P-well PWF may be formed at a less depth or the same or substantially the same depth from the peripheral circuit active surface PSBA than or as the peak of the dopant concentration of the front N-well NWF. The front P-well PWF may be formed to have a higher dopant concentration than a dopant concentration of the preliminary peripheral circuit substrate PSUBP in which the front P-wells PWF, the front N-wells NWF, and the deep front N-well DNWF are not formed. For example, a value of the peak of the dopant concentration of the front P-well PWF may be greater than a value of a peak of a dopant concentration of a portion of the preliminary peripheral circuit substrate PSUBP in which each of the front P-wells PWF, the front N-wells NWF, and the deep front N-wells DNWF are not formed.

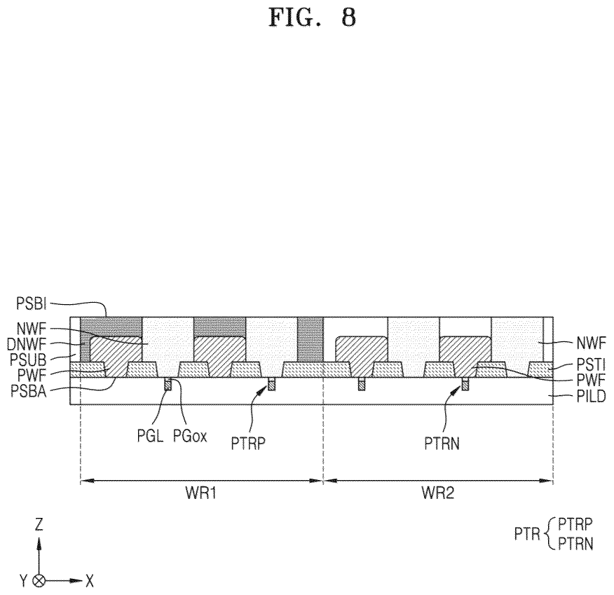

A depth used herein refers to a distance in the vertical direction (Z direction) from the peripheral circuit active surface PSBA or the preliminary peripheral circuit inactive surface PSBB of the preliminary peripheral circuit substrate PSUBP into the preliminary peripheral circuit substrate PSUBP, or refers to a distance in the vertical direction (Z direction) from the peripheral circuit active surface PSBA or the peripheral circuit inactive surface PSBI of the peripheral circuit substrate PSUB into the peripheral circuit substrate PSUB shown in FIG. 8.

The preliminary peripheral circuit substrate PSUBP may have a first well region WR1 and a second well region WR2 that are different from each other. The first ion implantation IPF1 may be performed only on the first well region WR1, and the deep front N-well DNWF may be formed on the first well region WR1 but may not be formed on the second well region WR2. The second ion implantation IPF2 and the third ion implantation IPF3 may be performed on different portions, respectively, of each of the first well region WR1 and the second well region WR2. For example, some of the front P-wells PWF and some of the front N-wells NWF may be formed in different portions of the first well region WR1, and some other front P-wells PWF and some other front N-wells NWF may be formed in different portions of the second well region WR2. Some of the front P-wells PWF and some of the front N-wells NWF that are formed in the first well region WR1 may be formed within the deep front N-well NWF.

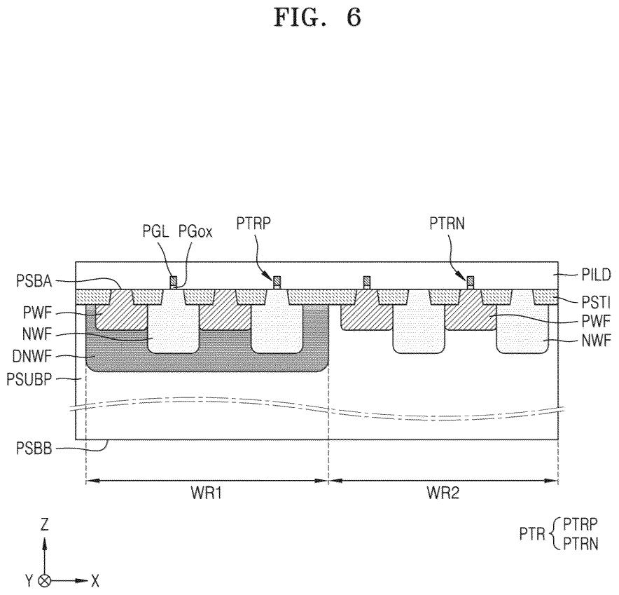

Referring to FIG. 6, a circuit gate insulating layer PGox, a circuit gate electrode PGL, and a circuit interlayer insulating layer PILD are formed on the peripheral circuit active surface PSBA of the preliminary peripheral circuit substrate PSUBP. The circuit gate insulating layer PGox, the circuit gate electrode PGL, and a portion of the preliminary peripheral circuit substrate PSUBP may constitute a peripheral circuit transistor PTR. The peripheral circuit transistor PTR may include a p-type transistor PTRP and an n-type transistor PTRN. For example, the circuit gate insulating layer PGox, the circuit gate electrode PGL, and a portion of the front N-well NWF may constitute a p-type transistor PTRP, and the circuit gate insulating layer PGox, the circuit gate electrode PGL, and a portion of the front P-well PWF may constitute an n-type transistor PTRN. P-type impurity regions may be formed in portions of the front N-well NWF adjacent to the circuit gate electrode PGL constituting the p-type transistor PTRP, and thus may become a source region and a drain region of the p-type transistor PTRP, and n-type impurity regions may be formed in portions of the front P-well PWF adjacent to the circuit gate electrode PGL constituting the n-type transistor PTRN, and thus may become a source region and a drain region of the n-type transistor PTRN.

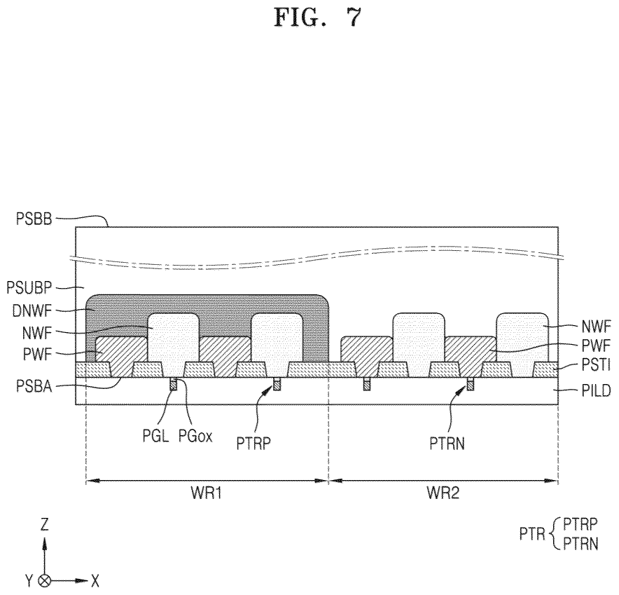

Referring to FIG. 7, a resultant structure of FIG. 6 is turned upside down so that the preliminary peripheral circuit inactive surface PSBB of the preliminary peripheral circuit substrate PSUBP faces upward and the circuit interlayer insulating layer PILD faces downward.

Referring to FIGS. 7 and 8, a portion of the preliminary peripheral circuit substrate PSUBP is removed from the preliminary peripheral circuit inactive surface PSBB of the preliminary peripheral circuit substrate PSUBP to form the peripheral circuit substrate PSUB. A portion of the preliminary peripheral circuit substrate PSUBP may be removed by backgrinding or back lap. The peripheral circuit substrate PSUB may have a peripheral circuit active surface PSBA and a peripheral circuit inactive surface PSBI that are opposite to each other. The peripheral circuit active surface PSBA of the peripheral circuit substrate PSUB may be the peripheral circuit active surface PSBA of the preliminary peripheral circuit substrate PSUBP, and the peripheral circuit inactive surface PSBI of the peripheral circuit substrate PSUB may be an exposed surface of the peripheral circuit substrate PSUB formed by removing a portion of the peripheral circuit substrate PSUB from the preliminary peripheral circuit inactive surface PSBB of the preliminary peripheral circuit substrate PSUBP.

According to some example embodiments, when a relatively small portion of the preliminary peripheral circuit substrate PSUBP is removed from the preliminary peripheral circuit inactive surface PSBB, the front N-well NWF and the deep front N-well DNWF may be exposed via the peripheral circuit inactive surface PSBI. In a process of removing a portion of the preliminary peripheral circuit substrate PSUBP from the preliminary peripheral circuit inactive surface PSBB, portions of the deep front N-well DNWF located on some of the front N-wells NWF of FIG. 7 may be removed. For example, in the first well region WR1 of the peripheral circuit substrate PSUB, the deep front N-well DNWF may not overlap the front N-well NWF in the vertical direction (Z direction), and may overlap the front P-well PWF in the vertical direction (Z direction). According to some example embodiments, when a relatively large portion of the preliminary peripheral circuit substrate PSUBP is removed from the preliminary peripheral circuit inactive surface PSBB, the front P-well PWF, the front N-well NWF, and the deep front N-well DNWF may be exposed via the peripheral circuit inactive surface PSBI. According to some example embodiments, when the deep front N-well DNWF is not formed, the front N-well NWF may be exposed via the peripheral circuit inactive surface PSBI, or the front P-well PWF and the front N-well NWF may be exposed together.

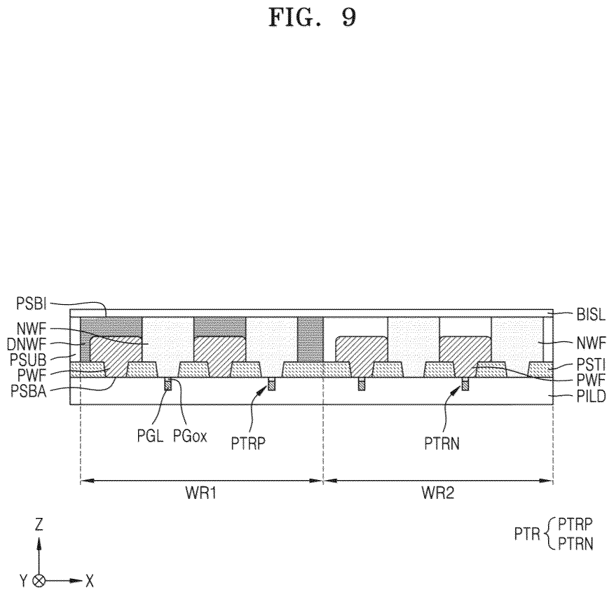

Referring to FIG. 9, a back protective insulating layer BISL covering the peripheral circuit inactive surface PSBI is formed. For example, the back (e.g., rear) protective insulating layer BISL may include an oxide. According to some example embodiments, the back protective insulating layer BISL may not be formed and may be omitted.

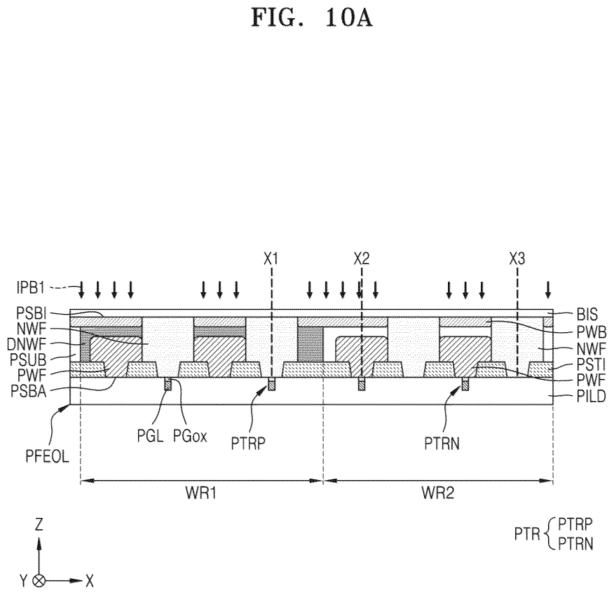

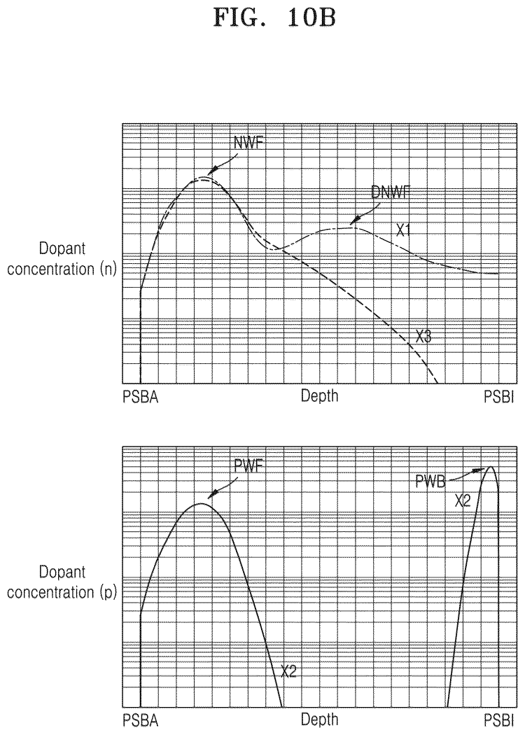

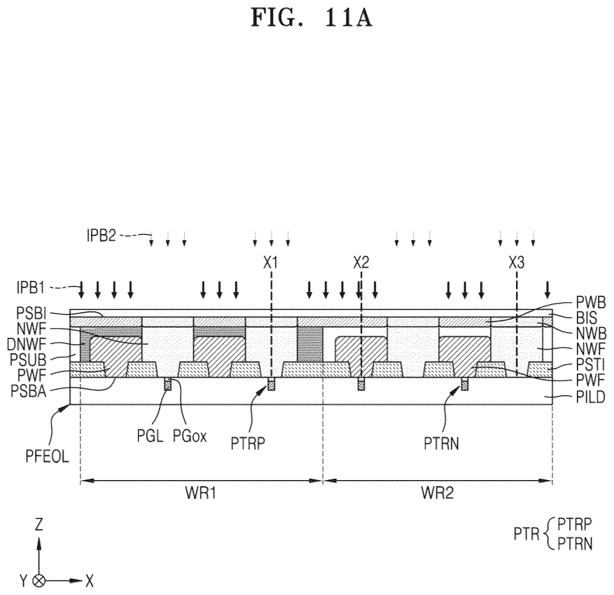

Referring to FIGS. 10A and 10B, ion implantation may be performed through the peripheral circuit inactive surface PSBI of the peripheral circuit substrate PSUB to form back P-wells PWB, thereby forming the peripheral circuit device layer PFEOL. Each of the back P-wells PWB may be formed to extend from the peripheral circuit inactive surface PSBI into the peripheral circuit substrate PSUB. The back P-wells PWB may be formed by implanting p-type impurities into portions of the peripheral circuit substrate PSUB adjacent to the peripheral circuit inactive surface PSBI via a fourth ion implantation IPB1. The fourth ion implantation IPB1 may be referred to as a first back ion implantation or a back ion implantation.

The back P-wells PWB may be formed in portions of the peripheral circuit substrate PSUB adjacent to the peripheral circuit inactive surface PSBI and overlapping the front P-wells PWF in the vertical direction (Z direction). The back P-wells PWB may be formed in portions of the peripheral circuit substrate PSUB adjacent to the peripheral circuit inactive surface PSBI and not overlapping the front N-wells NWF in the vertical direction (Z direction). For example, all of the front P-wells PWF may overlap the back P-wells PWB in the vertical direction (Z direction), and all of the front N-wells NWF may not overlap the back P-wells PWB in the vertical direction (Z direction). According to some example embodiments, the back P-wells PWB may be formed in portions of the peripheral circuit substrate PSUB in which portions of the deep front N-well DNWF exposed to the peripheral circuit inactive surface PSBI are formed, and in portions of the peripheral circuit substrate PSUB in which wells, such as the front P-well PWF, the front N-well NWF, and the deep front N-well DNWF, are not formed. According to some example embodiments, the back P-well PWB may be formed to contact the front N-well NWF and the deep front N-well DNWF but not contact the front P-well PWF.

FIG. 10B shows a doping profile measured according to depths from the peripheral circuit active surface PSBA toward the interior of the peripheral circuit substrate PSUB along X1, X2, and X3 of FIG. 10A. A peak of a dopant concentration of the back P-well PWB may be formed at a portion of the peripheral circuit substrate PSUB adjacent to the peripheral circuit inactive surface PSBI but spaced apart from the peripheral circuit inactive surface PSBI in a length direction, e.g., in the vertical direction. A doping profile of the back P-well PWB may decrease from the peak of the dopant concentration of the back P-well PWB toward each of the peripheral circuit active surface PSBA and the peripheral circuit inactive surface PSBI. A depth of the peak of the dopant concentration of the back P-well PWB from the peripheral circuit inactive surface PSBI may be less than a depth of the peak of the dopant concentration of the front P-well PWF from the peripheral circuit active surface PSBA. The back P-well PWB may be formed to have a higher dopant concentration than the dopant concentration of the front P-well PWF. For example, a value of the peak of the dopant concentration of the back P-well PWB may be greater than a value of the peak of the dopant concentration of the front P-well PWF. A rate at which the doping profile of the back P-well PWB decreases from the peak of the dopant concentration of the back P-well PWB toward the peripheral circuit inactive surface PSBI, e.g., a rate at which a depth from the peripheral circuit inactive surface PSBI decreases, may be higher (e.g., greater) than a rate at which the doping profile of the back P-well PWB decreases from the peak of the dopant concentration of the back P-well PWB toward the peripheral circuit active surface PSBA, e.g., a rate at which a depth from the peripheral circuit active surface PSBA increases. The doping profile of each of the front N-well NWF and the deep front N-well DNWF may be identical or substantially identical to the doping profile of each of the front N-well NWF and the deep front N-well DNWF shown in FIG. 5B. For example, the doping profile of each of the front N-well NWF and the deep front N-well DNWF may decrease from the peak of the dopant concentration of each of the front N-well NWF and the deep front N-well DNWF toward each of the peripheral circuit active surface PSBA and the peripheral circuit inactive surface PSBI. According to some example embodiments, a rate at which the doping profile of each of the front N-well NWF and the deep front N-well DNWF decreases from the peak of the dopant concentration of each of the front N-well NWF and the deep front N-well DNWF toward the peripheral circuit active surface PSBA, e.g., a rate at which a depth from the peripheral circuit active surface PSBA decreases, may be higher than a rate at which the doping profile of each of the front N-well NWF and the deep front N-well DNWF decreases from the peak of the dopant concentration of each of the front N-well NWF and the deep front N-well DNWF toward the peripheral circuit inactive surface PSBI, e.g., a rate at which a depth from the peripheral circuit inactive surface PSBI increases.

Referring to FIGS. 7 through 10B together, in a process of forming the peripheral circuit substrate PSUB by removing a portion of the preliminary peripheral circuit substrate PSUBP such as described with respect to FIG. 8, a dangling bond may occur on the peripheral circuit inactive surface PSBI, which may cause a leakage current between adjacent front N-wells NWF as shown in FIG. 10A. However, when the back P-well PWB is formed between portions of the peripheral circuit substrate PSUB that are adjacent to the peripheral circuit inactive surface PSBI and do not overlap the front N-wells NWF in the vertical direction (Z direction), e.g., between adjacent front N-wells NWF, a leakage current may be limited and/or prevented from occurring between the adjacent front N-wells NWF.

Thereafter, the peripheral circuit wiring layer PBEOL shown in FIG. 1 may be formed on the peripheral circuit inactive surface PSBI of the peripheral circuit device layer PFEOL and thus the peripheral circuit structure PRST shown in FIG. 1 may be formed, and then the peripheral circuit structure PRST may be bonded onto the cell array structure CST such that the peripheral circuit active surface PSBA faces the cell array structure CST, thereby forming the semiconductor device 1 shown in FIG. 1, or the peripheral circuit device layer PFEOL may be bonded onto the cell array structure CST such that the peripheral circuit active surface PSBA faces the cell array structure CST, and the peripheral circuit wiring layer PBEOL may be formed on the peripheral circuit inactive surface PSBI of the peripheral circuit device layer PFEOL, thereby forming the semiconductor device 1. The peripheral circuit wiring layer PBEOL shown in FIG. 2 may be formed on the peripheral circuit active surface PSBA of the peripheral circuit device layer PFEOL and thus the peripheral circuit structure PRST shown in FIG. 2 may be formed, and then the peripheral circuit structure PRST may be bonded onto the cell array structure CST such that the peripheral circuit inactive surface PSBI faces the cell array structure CST, thereby forming the semiconductor device 2 shown in FIG. 2, or the peripheral circuit device layer PFEOL may be bonded onto the cell array structure CST such that the peripheral circuit inactive surface PSBI faces the cell array structure CST, and the peripheral circuit wiring layer PBEOL may be formed on the peripheral circuit active surface PSBA of the peripheral circuit device layer PFEOL, thereby forming the semiconductor device 2. The semiconductor device 1 or the semiconductor device 2 may be formed such that the bonding structure BDST is interposed between the cell array structure CST and the peripheral circuit structure PRST.

Referring to FIGS. 1 through 10B, because the back P-well PWB is disposed between the portions of the peripheral circuit substrate PSUB that are adjacent to the peripheral circuit inactive surface PSBI and do not overlap the front N-wells NWF in the vertical direction (Z direction), e.g., between adjacent front N-wells NWF, the semiconductor device 1 or the semiconductor device 2 according to the inventive concepts may limit and/or prevent a leakage current from occurring between the adjacent front N-wells NWF, and/or thus may be highly integrated and may have improved operational reliability.

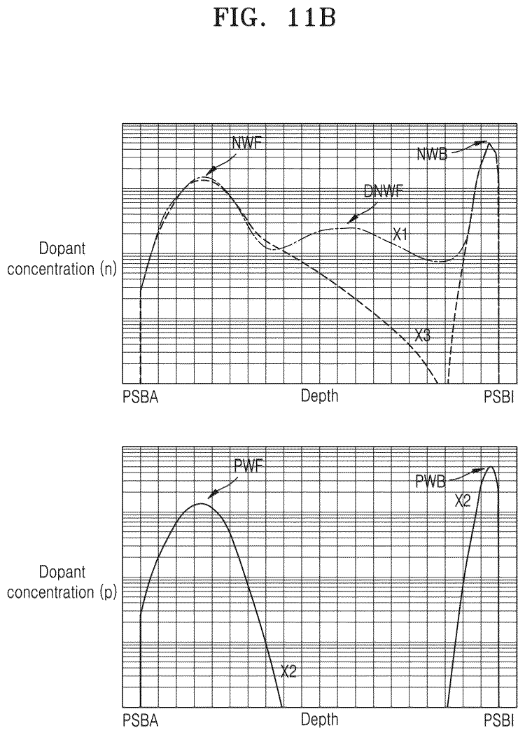

Referring to FIGS. 11A and 11B, ion implantation through the peripheral circuit inactive surface PSBI of the peripheral circuit substrate PSUB may be performed on a resultant structure of FIG. 9 to form the back P-wells PWB and the back N-wells NWB, thereby forming the peripheral circuit device layer PFEOL. Each of the back P-wells PWB and the back N-wells NWB may be formed to extend from the peripheral circuit inactive surface PSBI into the peripheral circuit substrate PSUB. The back P-wells PWB may be formed by implanting p-type impurities into portions of the peripheral circuit substrate PSUB adjacent to the peripheral circuit inactive surface PSBI via the fourth ion implantation IPB1, the rear N-wells NWB may be formed by implanting n-type impurities into portions of the peripheral circuit substrate PSUB adjacent to the peripheral circuit inactive surface PSBI via a fifth ion implantation IPB2, the fourth ion implantation IPB1 may be referred to as a first back ion implantation, and the fifth ion implantation IPB2 may be referred to as a second back ion implantation.

The back P-wells PWB may be formed on the portions of the peripheral circuit substrate PSUB adjacent to the peripheral circuit inactive surface PSBI and not overlapping the front N-wells NWF in the vertical direction (Z direction), and the back N-wells NWB may be formed on the portions of the peripheral circuit substrate PSUB adjacent to the peripheral circuit inactive surface PSBI and overlapping the front N-wells NWF in the vertical direction (Z direction). For example, the back N-wells NWB may be formed on portions of the peripheral circuit substrate PSUB on which the front N-wells NWF exposed to the peripheral circuit inactive surface PSBI are formed.

FIG. 11B shows a doping profile measured according to depths from the peripheral circuit active surface PSBA toward the interior of the peripheral circuit substrate PSUB along X1, X2, and X3 of FIG. 11A. A peak of a dopant concentration of the back N-well NWB may be formed at a portion of the peripheral circuit substrate PSUB adjacent to the peripheral circuit inactive surface PSBI. A depth of the peak of the dopant concentration of the back N-well NWB from the peripheral circuit inactive surface PSBI may be less than a depth of the peak of the dopant concentration of the front N-well NWF from the peripheral circuit active surface PSBA. The back N-well NWB may be formed to have a higher dopant concentration than the dopant concentration of the front N-well NWF. For example, a value of the peak of the dopant concentration of the back N-well NWB may be greater than a value of the peak of the dopant concentration of the front N-well NWF. A rate at which a doping profile of the back N-well NWB decreases from the peak of the dopant concentration of the back N-well NWB toward the peripheral circuit inactive surface PSBI, e.g., a rate at which a depth from the peripheral circuit inactive surface PSBI decreases, may be higher than a rate at which the doping profile of the back N-well NWB decreases from the peak of the dopant concentration of the back N-well NWB toward the peripheral circuit active surface PSBA, e.g., a rate at which a depth from the peripheral circuit active surface PSBA increases. The dopant concentration of each of the front P-well PWF and the back P-well PWB may be the same or substantially the same as the dopant concentration of each of the front P-well PWF and the back P-well PWB shown in FIG. 10B.

Referring to FIGS. 7 through 9 and FIGS. 11A and 11B, in a process of forming the peripheral circuit substrate PSUB by removing a portion of the preliminary peripheral circuit substrate PSUBP, resistance characteristics of each of the front N-wells NWF and the front P-wells PWF may deteriorate. However, formation of the back N-wells NWB and the back P-wells PWB may limit and/or prevent the resistance characteristics of each of the back N-wells NWB and the back P-wells PWB from deteriorating.

Thereafter, the peripheral circuit wiring layer PBEOL shown in FIG. 1 may be formed on the peripheral circuit inactive surface PSBI of the peripheral circuit device layer PFEOL and thus the peripheral circuit structure PRST shown in FIG. 1 may be formed, and then the peripheral circuit structure PRST may be bonded onto the cell array structure CST such that the peripheral circuit active surface PSBA faces the cell array structure CST, thereby forming the semiconductor device 1 shown in FIG. 1, or the peripheral circuit device layer PFEOL may be bonded onto the cell array structure CST such that the peripheral circuit active surface PSBA faces the cell array structure CST, and the peripheral circuit wiring layer PBEOL may be formed on the peripheral circuit inactive surface PSBI of the peripheral circuit device layer PFEOL, thereby forming the semiconductor device 1. Alternatively, the peripheral circuit wiring layer PBEOL shown in FIG. 2 may be formed on the peripheral circuit active surface PSBA of the peripheral circuit device layer PFEOL and thus the peripheral circuit structure PRST shown in FIG. 2 may be formed, and then the peripheral circuit structure PRST may be bonded onto the cell array structure CST such that the peripheral circuit inactive surface PSBI faces the cell array structure CST, thereby forming the semiconductor device 2 shown in FIG. 2, or the peripheral circuit device layer PFEOL may be bonded onto the cell array structure CST such that the peripheral circuit inactive surface PSBI faces the cell array structure CST, and the peripheral circuit wiring layer PBEOL may be formed on the peripheral circuit active surface PSBA of the peripheral circuit device layer PFEOL, thereby forming the semiconductor device 2. The semiconductor device 1 or the semiconductor device 2 may be formed such that the bonding structure BDST is interposed between the cell array structure CST and the peripheral circuit structure PRST.

Referring to FIGS. 1 through 9 and FIGS. 11A and 11B, because the back P-well PWB is disposed between the portions of the peripheral circuit substrate PSUB that are adjacent to the peripheral circuit inactive surface PSBI and do not overlap the front N-wells NWF in the vertical direction (Z direction), e.g., between adjacent front N-wells NWF, the semiconductor device 1 or the semiconductor device 2 according to the inventive concepts may limit and/or prevent a leakage current from occurring between the adjacent front N-wells NWF, and the back N-wells NWB and the back P-wells PWB may limit and/or prevent the resistance characteristics of each of the front N-wells NWF and the front P-wells PWF from deteriorating. Thus, the semiconductor device 1 or the semiconductor device 2 according to the inventive concepts may be highly integrated and/or may have improved operational reliability.

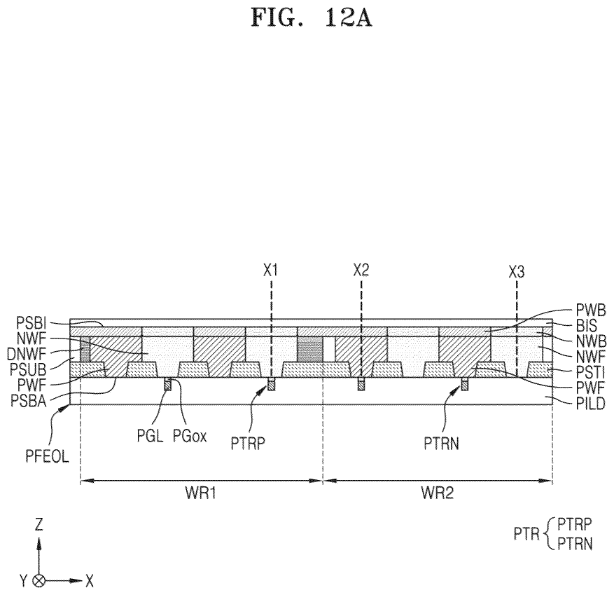

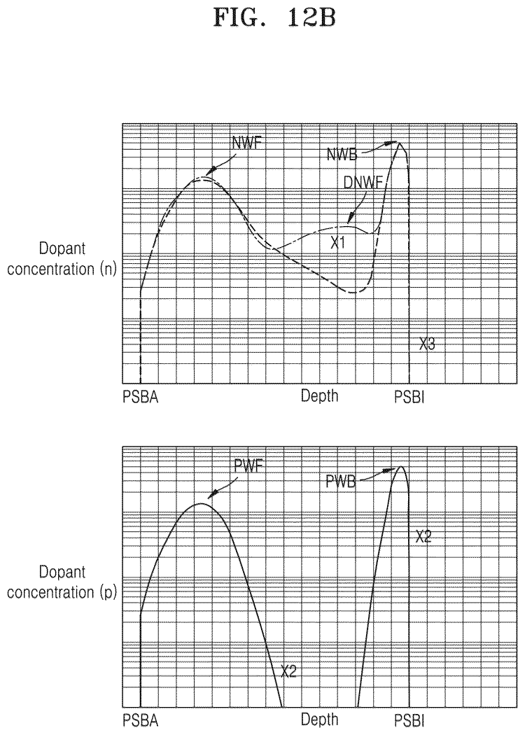

FIGS. 12A, 13A, and 14A are cross-sectional views illustrating a method of manufacturing a peripheral circuit structure included in a semiconductor device according to some example embodiments, and FIGS. 12B, 13B, and 14B are graphs showing doping profiles of a peripheral circuit substrate included in the peripheral circuit structure. FIGS. 12A, 12B, 13A, 13B, 14A, and 14B show cross-sectional views and doping profiles of the peripheral circuit substrate PSUB according to an increase in the amount (e.g., a thickness) of a portion of the preliminary peripheral circuit substrate PSUBP removed during a process of forming the peripheral circuit substrate PSUB by removing a portion of the preliminary peripheral circuit substrate PSUBP described above with reference to FIGS. 7 and 8.

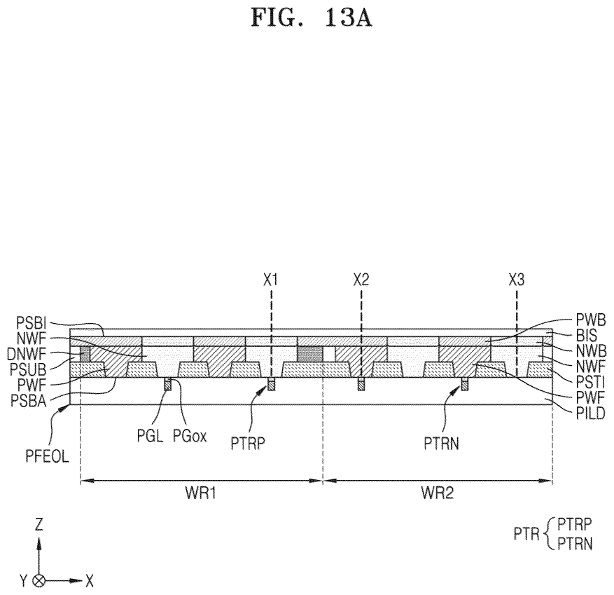

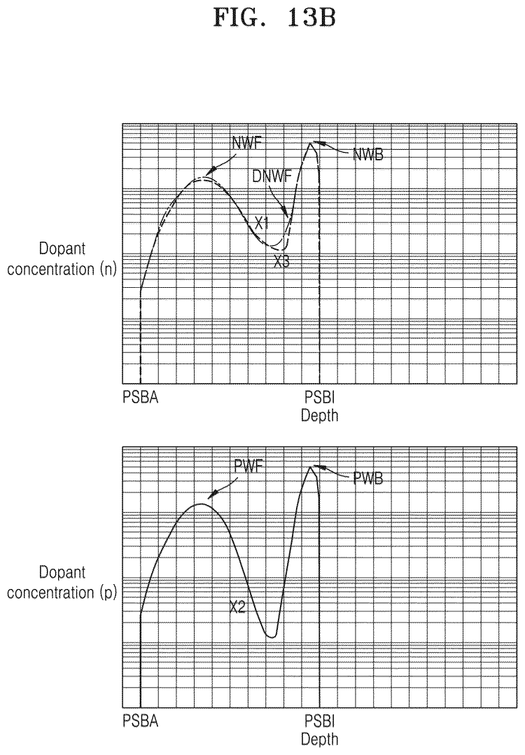

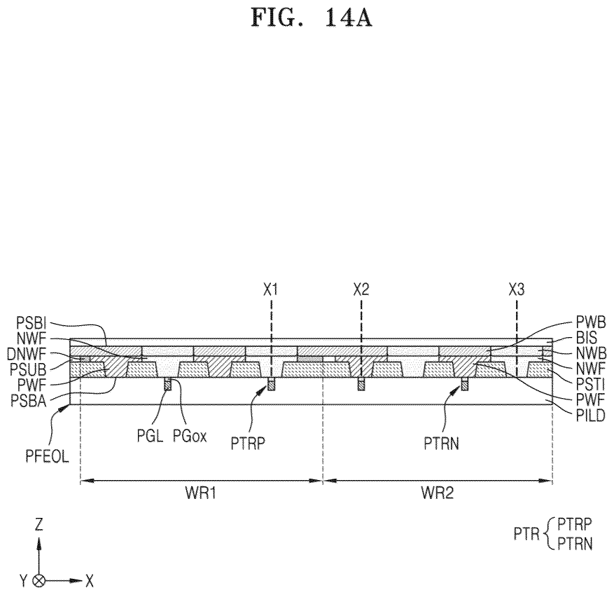

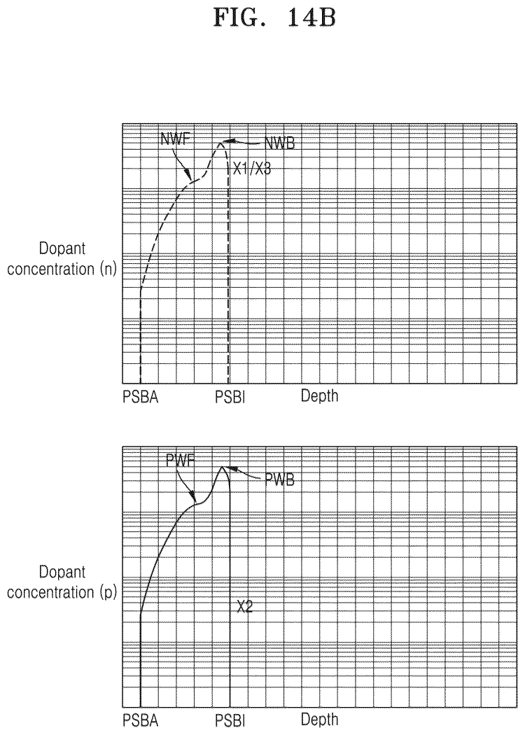

Referring to FIGS. 12A, 12B, 13A, 13B, 14A, and 14B, the back P-well PWB may be formed to be in contact with the front P-well PWF. As shown in FIG. 12B, the peak of the dopant concentration of the deep front N-well DNWF may be closer to the peak of the dopant concentration of the back N-well NWB than the peak of the dopant concentration of the front N-well NWF is. Alternatively, as shown in FIGS. 13B and 14B, the peak of the dopant concentration of the deep front N-well DNWF may overlap a dopant concentration profile of the back N-well NWB, making it difficult to distinguish them. Alternatively, as shown in FIG. 14B, at least a portion of a dopant concentration profile of the front N-well NWF may overlap the dopant concentration profile of the back N-well NWB, making the peak of the dopant concentration of the front N-well NWF appear small or making it difficult to distinguish them.

According to some example embodiments, in the process of forming the peripheral circuit substrate PSUB by removing a portion of the preliminary peripheral circuit substrate PSUBP as described above with reference to FIGS. 7 and 8, when a relatively large portion of the preliminary peripheral circuit substrate PSUBP is removed from the preliminary peripheral circuit inactive surface PSBB, portions of the deep front N-well DNWF disposed on some of the front P-wells PWF and some of the front N-wells NWF shown in FIG. 7 may be removed. For example, in the first well region WR1 of the peripheral circuit substrate PSUB, the deep front N-well DNWF may not overlap each of the front P-well PWF and the front N-well NWF in the vertical direction (Z direction).

Although examples where the back P-wells PWB and the back N-wells NWB described above with reference to FIGS. 11A and 11B are formed has been described with reference to FIGS. 12A, 12B, 13A, 13B, 14A, and 14B, it will be clearly understood by those skilled in the art that changing the depth of the peripheral circuit inactive surface PSBI in the concentration profile for an n-type dopant shown in FIG. 10B corresponds to an example where only the back P-wells PWB described above with reference to FIGS. 10A and 10B are formed.

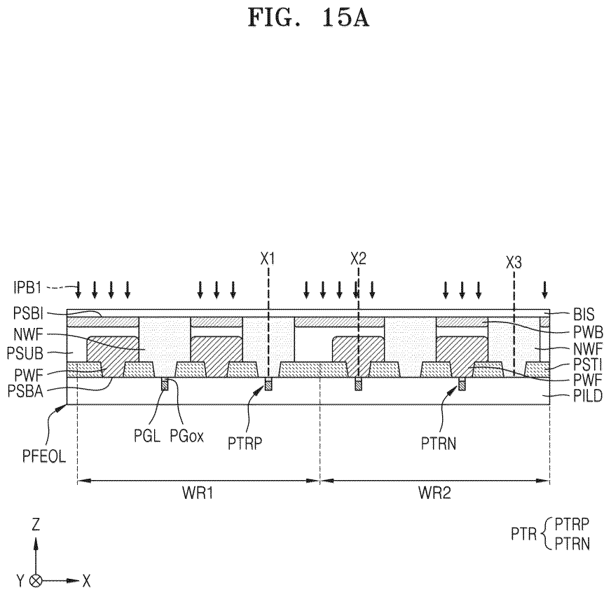

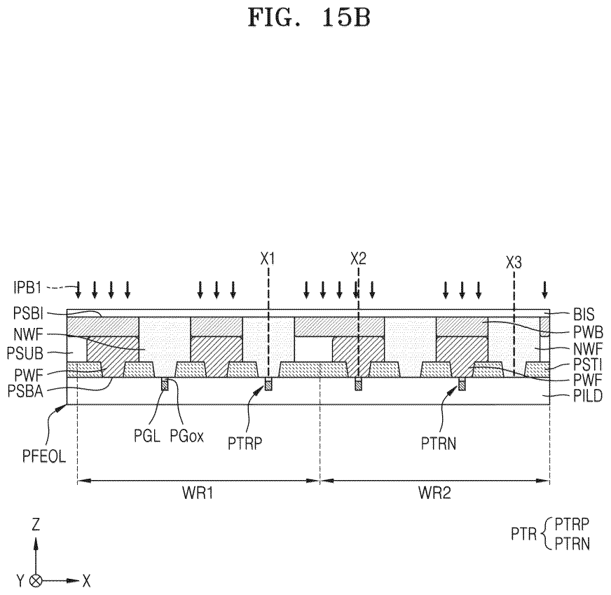

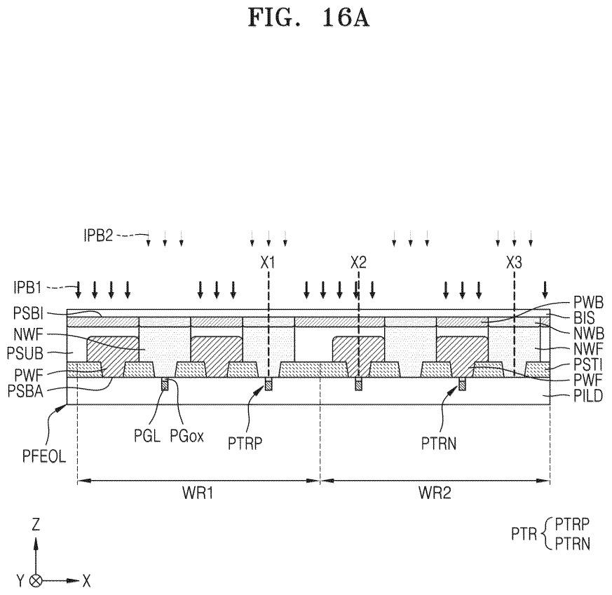

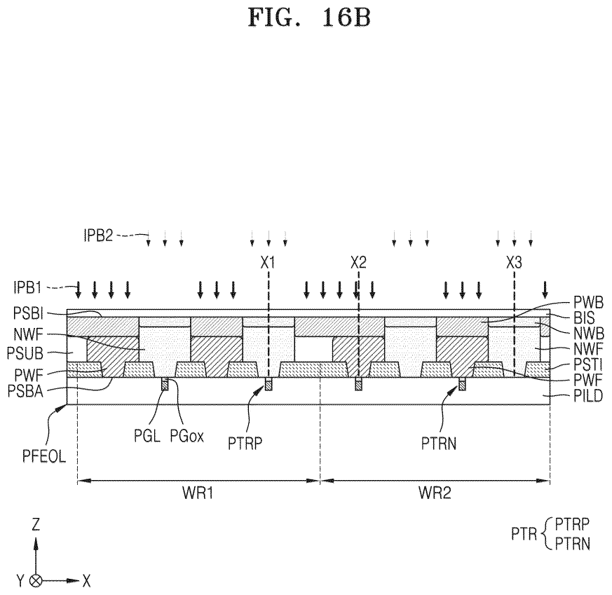

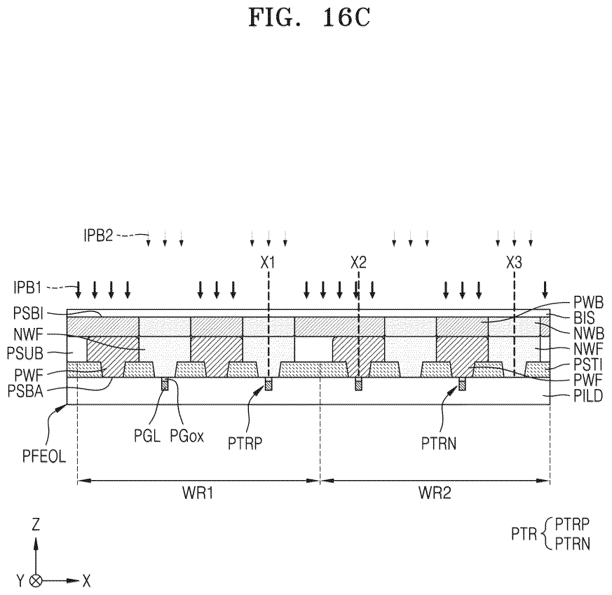

Each of FIGS. 15A, 15B, 16A, 16B, and 16C is a cross-sectional view illustrating a method of manufacturing a peripheral circuit structure included in a semiconductor device according to some example embodiments.

Referring to FIG. 15A, the deep front N-well DNWF described above with reference to FIGS. 5A and 5B may not be formed and only the front P-wells PWF and the front N-wells NWF may be formed, and then the back P-wells PWB may be formed via the fourth ion implantation IPB1 as described above with reference to FIGS. 10A and 10B. The back P-wells PWB may be formed to have a relatively small depth from the peripheral circuit inactive surface PSBI so as to be spaced apart from the front P-wells PWF without being in contact with the front P-wells PWF.

Referring to FIG. 15B, the deep front N-well DNWF described above with reference to FIGS. 5A and 5B may not be formed and only the front P-wells PWF and the front N-wells NWF may be formed, and then the back P-wells PWB may be formed via the fourth ion implantation IPB1 as described above with reference to FIGS. 10A and 10B. The back P-wells PWB may be formed to have a relatively large depth from the peripheral circuit inactive surface PSBI so as to be formed in contact with the front P-wells PWF.

Referring to FIG. 16A, the deep front N-well DNWF described above with reference to FIGS. 5A and 5B may not be formed and only the front P-wells PWF and the front N-wells NWF may be formed, and then, as described above with reference to FIGS. 11A and 11B, the back P-wells PWB may be formed via the fourth ion implantation IPB1 and the back N-wells NWB may be formed via the fifth ion implantation IPB2. The back P-wells PWB may be formed to have a relatively small depth from the peripheral circuit inactive surface PSBI so as to be spaced apart from the front P-wells PWF without being in contact with the front P-wells PWF.

Referring to FIG. 16B, the deep front N-well DNWF described above with reference to FIGS. 5A and 5B may not be formed and only the front P-wells PWF and the front N-wells NWF may be formed, and then, as described above with reference to FIGS. 11A and 11B, the back P-wells PWB may be formed via the fourth ion implantation IPB1 and the back N-wells NWB may be formed via the fifth ion implantation IPB2. The back P-wells PWB may be formed to have a relatively large depth from the peripheral circuit inactive surface PSBI so as to be formed in contact with the front P-wells PWF, and the back N-wells NWB may be formed to have a relatively small depth from the peripheral circuit inactive surface PSBI, compared to the back P-wells PWB.

Referring to FIG. 16C, the deep front N-well DNWF described above with reference to FIGS. 5A and 5B may not be formed and only the front P-wells PWF and the front N-wells NWF may be formed, and then, as described above with reference to FIGS. 11A and 11B, the back P-wells PWB may be formed via the fourth ion implantation IPB1 and the back N-wells NWB may be formed via the fifth ion implantation IPB2. The back P-wells PWB may be formed to have a relatively large depth from the peripheral circuit inactive surface PSBI so as to be formed in contact with the front P-wells PWF, and similar to the back P-wells PWB, the back N-wells NWB may be formed to have a relatively large depth from the peripheral circuit inactive surface PSBI.

In the process of forming the peripheral circuit substrate PSUB by removing a portion of the preliminary peripheral circuit substrate PSUBP as described above with reference to FIGS. 7 and 8, at least a portion of the dopant concentration profile of the deep front N-well DNWF may overlap the dopant concentration profile of the back N-well NWB, as shown in FIGS. 12A, 12B, 13A, 13B, 14A, and 14B, according to an increase in an amount (e.g., a thickness) of the portion of the preliminary peripheral circuit substrate PSUBP that is removed. Therefore, as shown in FIGS. 15A, 15B, 16A, 16B, and 16C, the deep front N-well DNWF described above with reference to FIGS. 5A and 5B may not be formed.

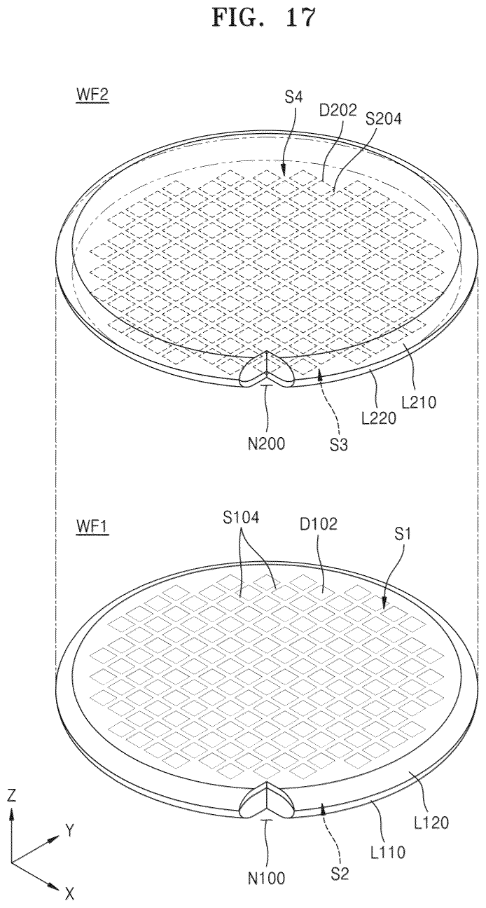

FIG. 17 is a perspective view for illustrating a method of manufacturing a semiconductor device, according to some example embodiments.

Referring to FIG. 17, a first wafer WF1 includes a plurality of first dies D102 and a first scribe lane region S104 extending between the plurality of first dies D102. The first wafer WF1 may include a first surface S1 and a second surface S2 opposite to each other. The first wafer WF1 may have a first notch N100 in a portion of a side surface thereof. A second wafer WF2 includes a plurality of second dies D202 and a second scribe lane region S204 extending between the plurality of second dies D202. The second wafer WF2 may include a third surface S3 and a fourth surface S4 opposite to each other. The second wafer WF2 may have a second notch N200 on a portion of a side surface thereof.

The first wafer WF1 includes a cell array layer L110 and a first bonding layer L120 covering the cell array layer L110, and the second wafer WF2 includes a peripheral circuit layer L210 and a second bonding layer L220 covering the peripheral circuit layer L210. The first bonding layer L120 may be arranged on the first surface S1 of the first wafer WF1, and the cell array layer L110 may be arranged on the second surface S2 of the first wafer WF1. The second bonding layer L220 may be arranged on the third surface S3 of the second wafer WF2, and the peripheral circuit layer L210 may be arranged on the fourth surface S4 of the second wafer WF2.

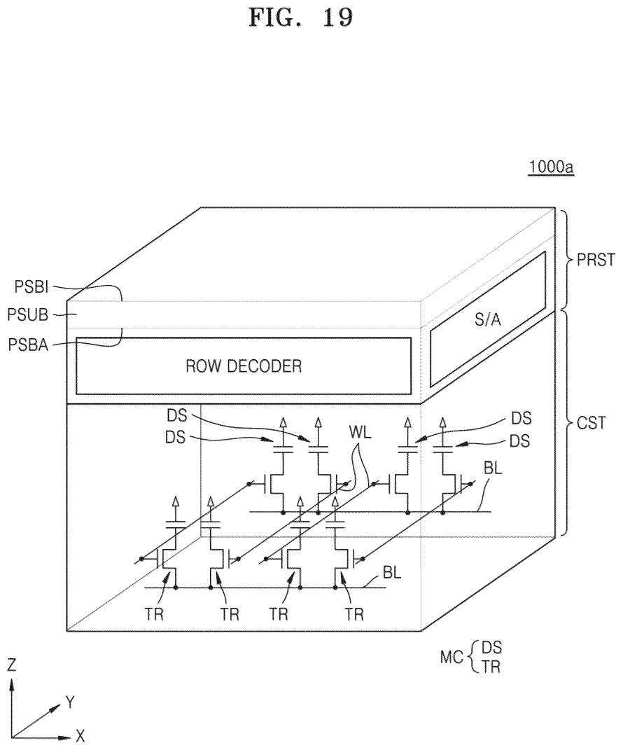

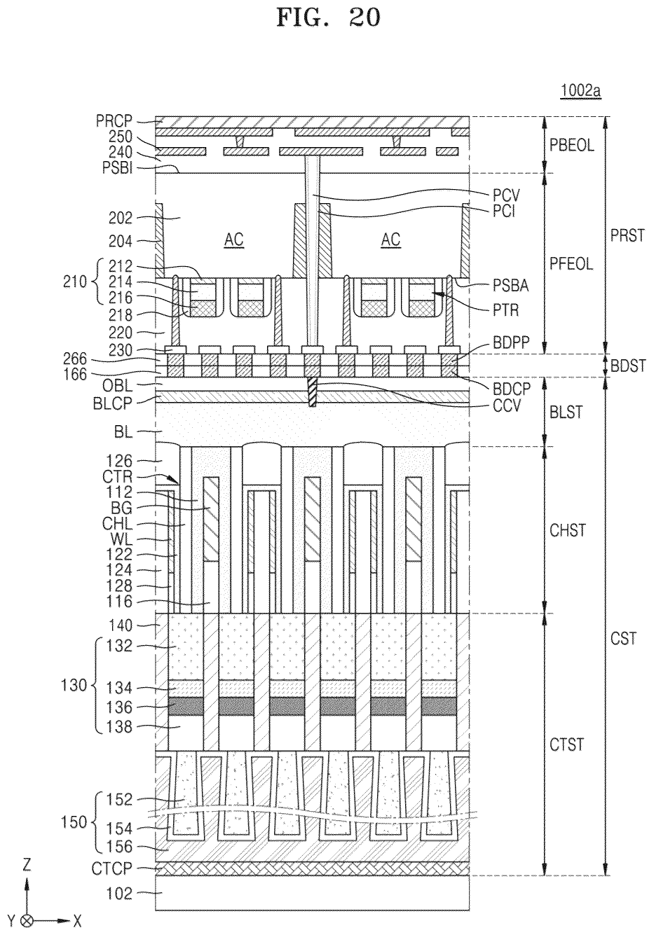

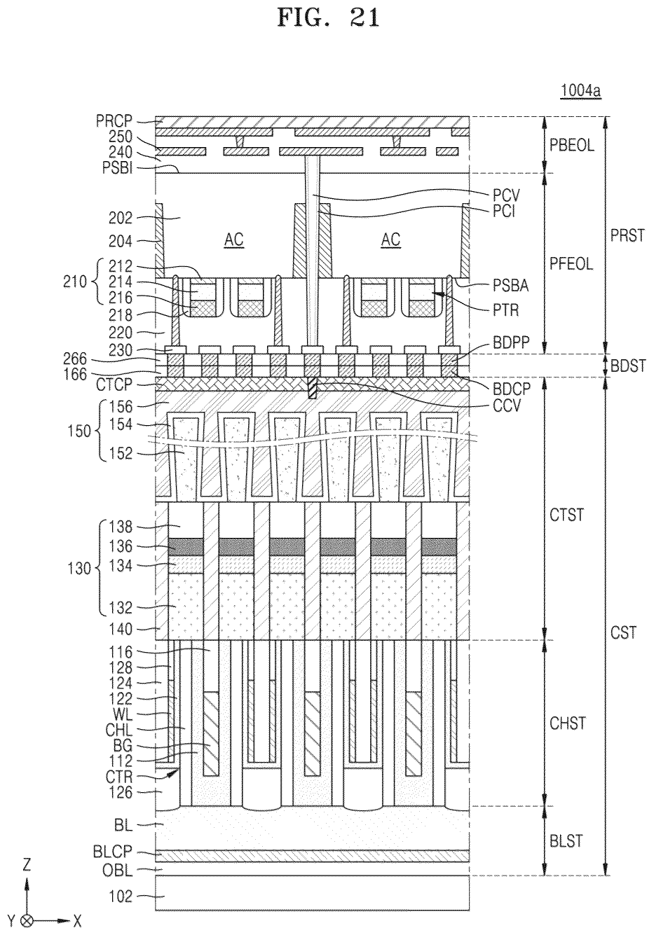

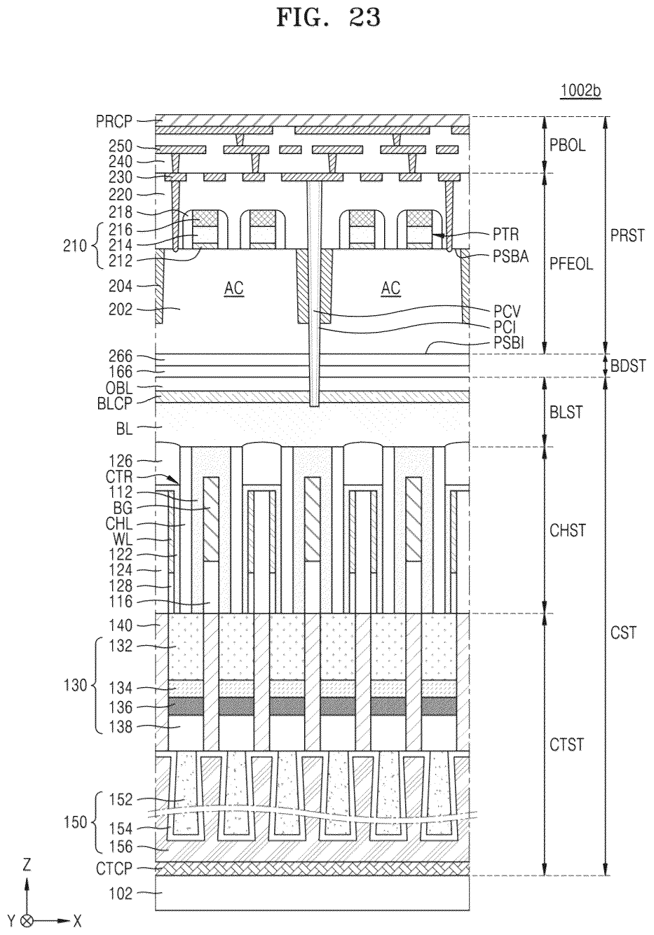

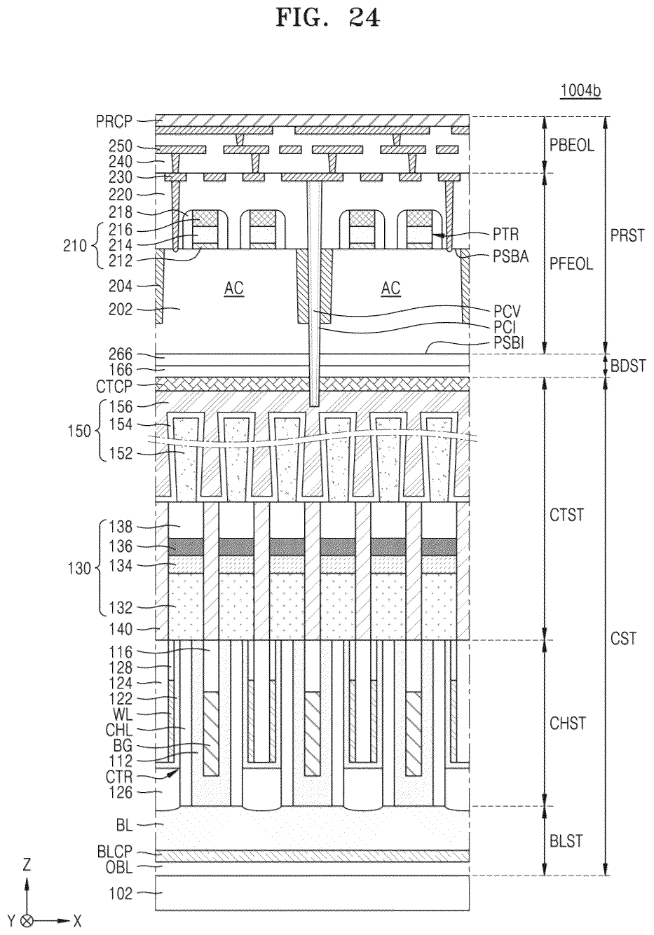

A portion of the cell array layer L110 of each of the plurality of first dies D102 may correspond to the cell array structure CST of each of FIG. 1, FIG. 2, and FIGS. 19 through 24. The peripheral circuit layer L210 of each of the plurality of second dies D202 may correspond to the peripheral circuit structure PRST of each of FIG. 1, FIG. 2, and FIGS. 19 through 24. A portion of the first bonding layer L120 of each of the plurality of first dies D102 may correspond to a portion of the bonding structure BDST of each of FIG. 1, FIG. 2, FIG. 20, FIG. 21, FIG. 23, and FIG. 24 that is adjacent to the cell array structure CST. A portion of the second bonding layer L220 of each of the plurality of second dies D202 may correspond to a portion of the bonding structure BDST of each of FIG. 1, FIG. 2, FIG. 20, FIG. 21, FIG. 23, and FIG. 24 that is adjacent to the peripheral circuit structure PRST.

After the first notch N100 of the first wafer WF1 and the second notch N200 of the second wafer WF2 are aligned with each other, the first surface S1 of the first wafer WF1 and the third surface S3 of the second wafer WF2 may contact each other while facing each other so that the first wafer WF1 and the second wafer WF2 may be bonded with each other. The first wafer WF1 and the second wafer WF2 may be bonded such that a plurality of first dies D102 and a plurality of second dies D202 corresponding to each other overlap each other. The first bonding layer L120 of the first wafer WF1 and the second bonding layer L220 of the second wafer WF2 may be bonded to each other to form the bonding structure BDST of each of FIG. 1, FIG. 2, FIG. 20, FIG. 21, FIG. 23, and FIG. 24. The first wafer WF1 and the second wafer WF2 may be bonded to each other by using a metal-oxide hybrid bonding method or a direct bonding method.

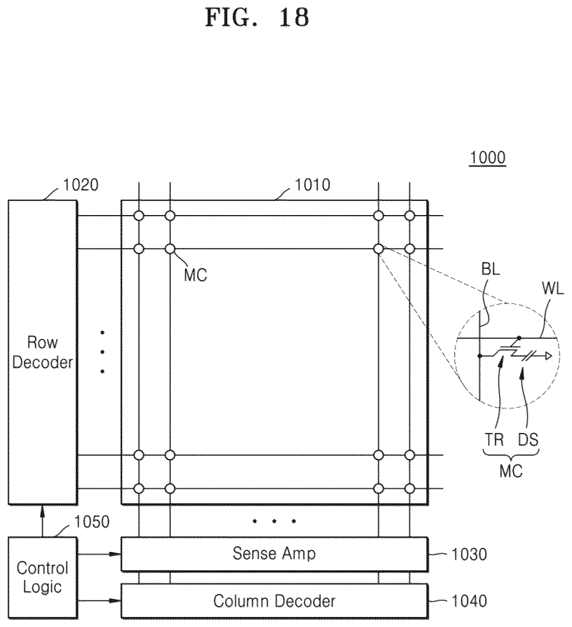

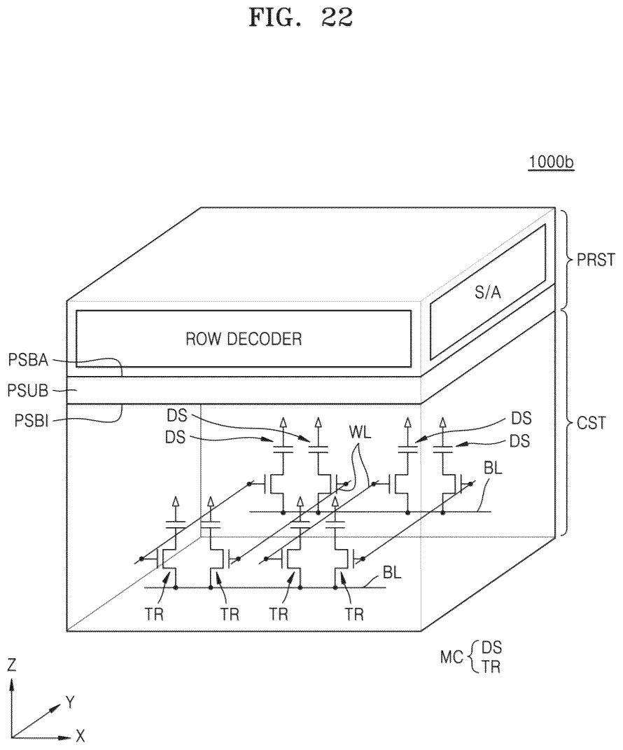

Thereafter, the first wafer WF1 and the second wafer WF2 bonded to each other may be diced along the first scribe lane region S104 and the second scribe lane region S204, thereby forming a plurality of semiconductor devices including a plurality of first dies D102 and a plurality of second dies D202 that correspond to each other. Each of the plurality of semiconductor devices may be one of the semiconductor device 1 shown in FIG. 1, the semiconductor device 2 shown in FIG. 2, a semiconductor device 1000 shown in FIG. 18, a semiconductor device 1000a shown in FIG. 19, a semiconductor device 1002a shown in FIG. 20, a semiconductor device 1004a shown in FIG. 21, a semiconductor device 1000b shown in FIG. 22, a semiconductor device 1002b shown in FIG. 23, and a semiconductor device 1004b shown in FIG. 24.

FIG. 18 is a block diagram of the semiconductor device 1000 according to some example embodiments.

Referring to FIG. 18, the semiconductor device 1000 may include a memory cell array 1010, a row decoder 1020, a sense amplifier 1030, a column decoder 1040, and a control logic unit 1050.

The memory cell array 1010 may include a plurality of memory cells MC arranged in a two-dimensional (2D) or three-dimensional (3D) manner. Each of the plurality of memory cells MC may be connected between a word line WL and a bit line BL that intersect each other.

Each of the plurality of memory cells MC may include a selection element TR and a data storage element DS, and the selection element TR and the data storage element DS may be electrically connected to each other in series. The selection element TR may be connected between the data storage element DS and the word line WL, and the data storage element DS may be connected to the bit line BL through the selection element TR.

For example, the selection element TR may include a transistor, a gate electrode of the transistor may be connected to the word line WL, and drain/source terminals of the transistor may be connected to the bit line BL and the data storage element DS, respectively. According to some example embodiments, the selection element TR may be a field effect transistor (FET). According to some example embodiments, the selection element TR may be, but is not limited to, a vertical channel transistor CTR as shown in FIGS. 20, 21, 23, and 24.

According to some example embodiments, the data storage element DS may be, but is not limited to, a capacitor 150 as shown in FIGS. 20, 21, 23, and 24. According to some other example embodiments, the data storage element DS may be implemented as a magnetic tunnel junction pattern or variable resistor that may be switched to two resistance states by an electrical pulse applied to a memory element. For example, the data storage element DS may include a phase-change material, perovskite compounds, transition metal oxide, magnetic materials, ferroelectric materials, or antiferromagnetic materials, each of which a crystal state changes according to the amount of current.

The row decoder 1020 may select one from the word lines WL of the memory cell array 1010 by decoding an externally input address. An address decoded by the row decoder 1020 may be provided to a sub word line driver, and the sub word line driver may provide a desired (and/or alternatively predetermined) voltage to each of a selected word line WL and unselected word lines WL in response to controls by control circuits.

The sense amplifier 1030 may sense and amplify the voltage difference between a selected bit line BL and a reference bit line according to the decoded address from the column decoder 1040, and may output a result of the sensing and amplifying.

The column decoder 1040 may provide a data transmission path between the sense amplifier 1030 and an external device (e.g., a memory controller). The column decoder 1040 may select one from the bit lines BL by decoding an externally input address.

The control logic unit 1050 may generate control signals for controlling operations of writing or reading data to or from the memory cell array 1010.

FIG. 19 is a schematic perspective view of the semiconductor device 1000a according to some example embodiments.

Referring to FIG. 19, the semiconductor device 1000a may include a cell array structure CST and a peripheral circuit structure PRST. The peripheral circuit structure PRST and the cell array structure CST shown in FIG. 19 are the same or substantially the same as the peripheral circuit structure PRST and the cell array structure CST shown in FIG. 1, and thus, any duplicate description may be omitted. The peripheral circuit structure PRST shown in FIG. 19 is depicted as including a portion of the peripheral circuit structure PRST of FIG. 1 that corresponds to the peripheral circuit device layer PFEOL, but may further include the peripheral circuit wiring layer PBEOL shown in FIG. 1. The bonding structure BDST of FIG. 1 may be interposed between the cell array structure CST and the peripheral circuit structure PRST included in the semiconductor device 1000a of FIG. 19.

The cell array structure CST may include a plurality of memory cells MC arranged in a 2D or 3D manner. Each of the plurality of memory cells MC may be connected between a word line WL and a bit line BL that intersect each other. Each of the plurality of memory cells MC may include a selection element TR and a data storage element DS, and the selection element TR and the data storage element DS may be electrically connected to each other in series. The selection element TR may be connected between the data storage element DS and the word line WL, and the data storage element DS may be connected to the bit line BL through the selection element TR.

The peripheral circuit structure PRST may be bonded onto the cell array structure CST. In the semiconductor device 1000a, the peripheral circuit structure PRST and the cell array structure CST may be bonded to each other by using a metal-oxide hybrid bonding method or a direct bonding method. The peripheral circuit structure PRST may include the peripheral circuit substrate PSUB. The peripheral circuit substrate PSUB may have a peripheral circuit active surface PSBA and a peripheral circuit inactive surface PSBI that are opposite to each other. The peripheral circuit structure PRST may be bonded onto the cell array structure CST such that the peripheral circuit active surface PSBA of the peripheral circuit substrate PSUB faces the cell array structure CST in the vertical direction (Z direction).

FIGS. 20 and 21 are cross-sectional views of the semiconductor devices 1002a and 1004a according to some example embodiments.

Referring to FIG. 20, the semiconductor device 1002a may include a cell array structure CST in which a plurality of memory cells are arranged, and a peripheral circuit structure PRST stacked on the cell array structure CST. For example, the plurality of memory cells may include a plurality of vertical channel transistors CTR. The cell array structure CST may include a capacitor structure CTST, a channel structure CHST, and a bit line structure BLST that are sequentially stacked in the vertical direction (Z direction). The peripheral circuit structure PRST may include a peripheral circuit transistor PTR constituted by a circuit gate structure 210. For example, the peripheral circuit transistor PTR constituted by the circuit gate structure 210 may be configured to transmit a signal and/or power to the plurality of memory cells included in the cell array structure CST. For example, the peripheral circuit transistor PTR constituted by the circuit gate structure 210 may form various circuits such as a command decoder, a control logic unit, an address buffer, a row decoder, a column decoder, a sense amplifier, and a data input/output circuit. According to some example embodiments, the semiconductor device 1002a may have a PoC structure in which the peripheral circuit structure PRST and the cell array structure CST overlap each other in the vertical direction (Z direction).

The capacitor structure CTST may be attached to a support substrate 102. The support substrate 102 may include, for example, a semiconductor material such as a Group IV semiconductor material, a Groups III and V semiconductor material, a Groups II and VI semiconductor material, or a Groups II and VI oxide semiconductor material. The capacitor structure CTST may include a plurality of contact plugs 130 arranged below the channel structure CHST, and a plurality of capacitors 150 respectively connected to the plurality of contact plugs 130.

The capacitor structure CTST may include a contact separation insulating layer 140 surrounding the plurality of contact plugs 130. Each of the plurality of contact plugs 130 may pass through the contact separation insulating layer 140. The plurality of contact plugs 130 may be spaced apart from each other in the first horizontal direction (X direction) and the second horizontal direction (Y direction) with the contact separation insulating layer 140 therebetween. According to some example embodiments, the contact separation insulating layer 140 may include silicon nitride. The contact separation insulating layer 140 may fill a space between the plurality of contact plugs 130. For example, the plurality of contact plugs 130 may respectively fill a plurality of contact holes, which are spaces defined by the contact separation insulating layer 140. The plurality of contact plugs 130 may be arranged in a matrix configuration to be apart from each other in the first horizontal direction (X direction) and the second horizontal direction (Y direction).

According to some example embodiments, the plurality of contact plugs 130 may each include metal, conductive metal nitride, metal silicide, doped polysilicon, or a combination thereof. For example, each of the plurality of contact plugs 130 may include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof.

According to some example embodiments, each of the plurality of contact plugs 130 may include a first conductive pattern 132, a second conductive pattern 134, a third conductive pattern 136, and a fourth conductive pattern 138 sequentially stacked beneath the channel structure CHST. The first conductive pattern 132 and the second conductive pattern 134 may include a semiconductor material, and the third conductive pattern 136 and the fourth conductive pattern 138 may include a metal-based material. For example, the first conductive pattern 132 may include undoped polysilicon, the second conductive pattern 134 may include doped polysilicon, the third conductive pattern 136 may include metal silicide, and the fourth conductive pattern 138 may include metal. However, some example embodiments are not limited thereto. For example, each of the plurality of contact plugs 130 may not include doped polysilicon, and may include a second conductive pattern 134 formed of doped polysilicon, a third conductive pattern 136 formed of metal silicide, and a fourth conductive pattern 138 formed of metal, which are sequentially stacked beneath the channel structure CHST. A stacked structure of the first conductive pattern 132 and the second conductive pattern 134, or the second conductive pattern 134 may be referred to as a buried contact (BC), a stacked structure of the fourth conductive pattern 138 may be referred to as a landing pad (LP), and the third conductive pattern 136 may be a metal silicide layer interposed between the BC and the LP. A stacked structure of the first conductive pattern 132 and the second conductive pattern 134, or the second conductive pattern 134 may be referred to as a semiconductor pattern, the third conductive pattern 136 may be referred to as a metal silicide pattern, and the fourth conductive pattern 138 may be referred to as a metal pattern.

The plurality of capacitors 150 may include a plurality of lower electrodes 152 connected to lower surfaces of the plurality of contact plugs 130, a capacitor dielectric layer 154 conformally covering respective lower surfaces of the plurality of lower electrodes 152, and an upper electrode 156 covering bottoms of the plurality of lower electrodes 152 with the capacitor dielectric layer 154 interposed between the upper electrode 156 and the plurality of lower electrodes 152. The fourth conductive pattern 138 included in each of the plurality of contact plugs 130 may function as an LP with which one lower electrode 152 selected from the plurality of lower electrodes 152 comes into contact.

Each of the plurality of lower electrodes 152 may have, but is not limited to, a solid pillar shape having a circular horizontal cross-section. According to some example embodiments, each of the plurality of lower electrodes 152 may have a cylindrical shape with a closed top. According to some example embodiments, the plurality of lower electrodes 152 may be arranged in lines in the first horizontal direction (X direction) and the second horizontal direction (Y direction) in a matrix pattern. According to some other example embodiments, the plurality of lower electrodes 152 may be arranged to zigzag in the first horizontal direction (X direction) or the second horizontal direction (Y direction) in a honeycomb pattern. The plurality of lower electrodes 152 may include, for example, impurity-doped silicon, a metal (such as, tungsten or copper), or a conductive metal compound (such as, titanium nitride).

The capacitor dielectric layer 154 may conformally cover lower surfaces of the plurality of lower electrodes 152. According to some example embodiments, the capacitor dielectric layer 154 may be formed as a high-k dielectric layer. According to some example embodiments, the capacitor dielectric layer 154 may include a metal oxide including at least one metal selected from hafnium (Hf), zirconium (Zr), aluminum (Al), niobium (Nb), cerium (Ce), lanthanum (La), tantalum (Ta), and titanium (Ti). According to some example embodiments, each of the plurality of lower electrodes 152 and the upper electrode 156 may include a metal, conductive metal oxide, conductive metal nitride, conductive metal oxynitride, or a combination thereof. According to some example embodiments, each of the plurality of lower electrodes 152 and the upper electrode 156 may include Nb, Nb oxide, Nb nitride, Nb oxynitride, Ti, Ti oxide, Ti nitride, Ti oxynitride, Co, Co oxide, Co nitride, Co oxynitride, Nb, Nb oxide, Nb nitride, Nb oxynitride, Sn, Sn oxide, Sn nitride, Sn oxynitride, or a combination thereof. According to some other example embodiments, each of the plurality of lower electrodes 152 and the upper electrode 156 may include TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba, Sr)RuO₃), CRO(CaRuO₃), LSCO((La, Sr)CoO₃), or a combination thereof. However, the material used to form each of the plurality of lower electrodes 152 and the upper electrode 156 is not limited to the materials above. According to some example embodiments, the upper electrode 156 may have a stacked structure including, in addition to the metal material, at least one of a doped semiconductor material layer and an interface layer. The doped semiconductor material layer may include, for example, at least one of doped polysilicon and doped polycrystalline silicon germanium (polySiGe). The interface layer may include, for example, at least one of metal oxide, metal nitride, metal carbide, and metal silicide.

The capacitor structure CTST may further include a capacitor capping layer CTCP covering a lower surface of the upper electrode 156. According to some example embodiments, the capacitor capping layer CTCP may function as a bonding insulating layer for bonding the support substrate 102 to the capacitor structure CTST. For example, after the capacitor structure CTST is formed, the capacitor structure CTST may be attached onto the support substrate 102 such that the capacitor capping layer CTCP of the capacitor structure CTST faces the support substrate 102. For example, the capacitor capping layer CTCP may include silicon oxide, silicon nitride, or a combination thereof.

The channel structure CHST may include a plurality of channel patterns (e.g., semiconductor patterns) CHL, a plurality of back gate electrodes BG, and a plurality of word lines WL. Each of the plurality of channel patterns CHL may extend in the vertical direction (Z direction). The plurality of back gate electrodes BG and the plurality of word lines WL may each extend in the second horizontal direction (Y direction).

Each of the plurality of channel patterns CHL may be disposed on a corresponding contact plug 130 among the plurality of contact plugs 130. For example, the plurality of channel patterns CHL may be connected to respective one ends of the plurality of contact plugs 130, and the plurality of lower electrodes 152 of the plurality of capacitors 150 may be connected to respective other ends of the plurality of contact plugs 130. Each of the plurality of channel patterns CHL may be connected to a lower electrode 152 via one contact plug 130 selected from the plurality of contact plugs 130. According to some example embodiments, the plurality of channel patterns CHL may be repeatedly arranged to be apart from each other in the first horizontal direction (X direction) and the second horizontal direction (Y direction) below the bit line structure BLST. Each of the plurality of channel patterns CHL may include a first end and a second end opposite to each other in the vertical direction (Z direction). Although FIG. 20 illustrates that each of the plurality of channel patterns CHL includes a vertical extension extending in the vertical direction (Z direction), this is merely an example, and some example embodiments are not limited thereto. According to some example embodiments, each of the plurality of channel patterns CHL may include the vertical extension, and a horizontal extension extending in the first horizontal direction (X direction) from one end of the vertical extension. According to some example embodiments, the horizontal extension of each of the plurality of channel patterns CHL may be positioned at the first end. Alternatively, according to some example embodiments, the horizontal extension of each of the plurality of channel patterns CHL may be positioned at the second end. In each of the plurality of channel patterns CHL, the first end may be connected to one contact plug 130 selected from among the plurality of contact plugs 130, and the second end may be connected to one bit line BL selected from among the plurality of bit lines BL included in the bit line structure BLST. According to some example embodiments, each of the plurality of channel patterns CHL may extend in the vertical direction (Z direction) between one selected from the plurality of bit lines BL and one selected from the plurality of contact plugs 130. According to some example embodiments, the channel pattern CHL may include a conductive region, for example, an impurity-doped well or an impurity-doped structure. Although not shown in the drawings, an impurity region functioning as a source/drain region may be formed in each of the first end and the second end.

According to some example embodiments, each of the plurality of channel patterns CHL may include a semiconductor material. For example, each of the plurality of channel patterns CHL may include silicon, for example, single-crystalline silicon, polycrystalline silicon, or amorphous silicon. According to some other example embodiments, each of the plurality of channel patterns CHL may include at least one selected from among Ge, SiGe, SiC, GaAs, InAs, and InP. According to some other example embodiments, each of the plurality of channel patterns CHL may include an oxide semiconductor material. Each of the plurality of channel patterns CHL may include at least one of a binary or ternary oxide semiconductor material including a first metal element, a ternary oxide semiconductor material including first and second metal elements different from each other, and a quaternary oxide semiconductor material including first, second and third metal elements different from each other.

The binary or ternary oxide semiconductor material may be, but is not limited to, one of ZnO (zinc oxide, ZnₓO), GaO (gallium oxide, GaₓO), TiO (tin oxide, TiₓO), ZnON (zinc oxynitride, ZnₓO_{y}N), IZO (indium zinc oxide, InₓZn_{y}O), GZO (gallium zinc oxide, GaₓZn_{y}O), TZO (tin zinc oxide, SnₓZn_{y}O), and TGO (tin gallium oxide, SnₓGa_{y}O). The quaternary oxide semiconductor material may be, but is not limited to, one of IGZO (indium gallium zinc oxide, InₓGa_{Y}Zn_{z}O), IGSO (indium gallium silicon oxide, InₓGa_{y}Si_{z}O), ITZO (indium tin zinc oxide, InₓSn_{Y}Zn_{z}O), IGTO (indium gallium tin oxide, InₓGa_{y}Sn_{z}O), ZZTO (zirconium zinc tin oxide, Zr_{X}Zn_{y}Sn_{z}O), HIZO (hafnium indium zinc oxide, HfₓIn_{Y}Zn_{z}O), GZTO (gallium zinc tin oxide, Ga_{X}Zn_{y}Sn_{z}O), AZTO (aluminum zinc tin oxide, Al_{X}Zn_{y}Sn_{z}O), YGZO (ytterbium gallium zinc oxide, YbₓGa_{Y}Zn_{z}O), and IAZO (indium aluminum zinc oxide).

According to some example embodiments, each of the plurality of channel patterns CHL may include a crystalline oxide semiconductor material or an amorphous oxide semiconductor material. When each of the plurality of channel patterns CHL includes a crystalline oxide semiconductor material, each of the plurality of channel patterns CHL may have at least one crystallinity among single crystallinity, polycrystallinity, spinel, and c-axis aligned crystallinity (CAAC). According to some example embodiments, each of the plurality of channel patterns CHL may be formed by stacking at least two layers including a first layer formed of a crystalline oxide semiconductor material and a second layer formed of an amorphous oxide semiconductor material. For example, each of the plurality of channel patterns CHL may be formed by sequentially stacking a first layer formed of a crystalline oxide semiconductor material, a second layer formed of an amorphous oxide semiconductor material, and a third layer formed of a crystalline oxide semiconductor material below the bit line structure BLST.

The plurality of back gate electrodes BG and the plurality of word lines WL may each extend in the second horizontal direction (Y direction) between the plurality of bit lines BL and the plurality of contact plugs 130. The plurality of back gate electrodes BG and the plurality of word lines WL may be apart from each other in the first horizontal direction (X direction). According to some example embodiments, each of the plurality of channel patterns CHL may be arranged between one back gate electrode BG and one word line WL adjacent to each other in the first horizontal direction (X direction), under a corresponding bit line BL among the plurality of bit lines BL. For example, each of the plurality of channel patterns CHL may face one back gate electrode BG on one side in the first horizontal direction (X direction), and may face one word line WL on the other side. According to some example embodiments, one back gate electrode BG and a pair of word lines WL may be alternately arranged between two adjacent channel patterns CHL in the first horizontal direction (X direction). According to some example embodiments, a pair of channel patterns CHL may be arranged on both sides of each of the plurality of back gate electrodes BG in the first horizontal direction (X direction), and a pair of word lines WL may be arranged apart from each of the plurality of back gate electrodes BG with the pair of channel patterns CHL interposed therebetween. For example, between a pair of back gate electrodes BG adjacent to each other in the first horizontal direction (X direction), one channel pattern CHL, one pair of word lines WL, and another channel pattern CHL may be sequentially arranged in the first horizontal direction (X direction). A pair of word lines WL arranged between two channel patterns CHL adjacent to each other in the first horizontal direction (X direction) may be spaced apart from each other in the first horizontal direction (X direction) with a separation insulating pattern 124 therebetween.

According to some example embodiments, each of the plurality of contact plugs 130 may include metal, conductive metal nitride, doped polysilicon, or a combination thereof. For example, each of the plurality of back gate electrodes BG may include, but is not limited to, Ti, TiN, Ta, TaN, Mo, Ru, W, WN, TiSiN, WSiN, doped polysilicon, or a combination thereof. Each of the plurality of word lines WL may include metal, conductive metal nitride, or a combination thereof. For example, each of the plurality of word lines WL may include, but is not limited to, Ti, TiN, Ta, TaN, Mo, Ru, W, WN, TiSiN, WSiN, or a combination thereof.

The channel structure CHST may include a plurality of back gate dielectric layers 112 each covering both sidewalls of each of the plurality of back gate electrodes BG in the first horizontal direction (X direction). Each of the plurality of back gate dielectric layers 112 may be interposed between one back gate electrode BG and one channel pattern CHL adjacent thereto. For example, each of the plurality of back gate dielectric layers 112 may be in contact with a back gate electrode BG and a channel pattern CHL. In FIG. 20, the back gate dielectric layer 112 is illustrated as being interposed between a back gate electrode BG and a bit line BL. However, some example embodiments are not limited thereto. For example, the back gate electrode BG and the bit line BL may further include an insulating pattern therebetween. The back gate electrode BG may be spaced apart from the plurality of bit lines BL in the vertical direction (Z direction) with the back gate dielectric layer 112 and/or the insulating pattern therebetween. According to some example embodiments, a capping insulating pattern 116 may be disposed between a back gate electrode BG and a plurality of contact plugs 130. According to some example embodiments, the capping insulating pattern 116 and the back gate electrode BG may be arranged to overlap each other in the vertical direction (Z direction), and each of both sidewalls of each of the capping insulating pattern 116 and the back gate electrode BG in the first horizontal direction (X direction) may be in contact with the back gate dielectric layer 112 and may be covered by the back gate dielectric layer 112. The back gate electrode BG may be spaced apart from the plurality of contact plugs 130 in the vertical direction (Z direction) with the capping insulating pattern 116 therebetween. According to some example embodiments, the capping insulating pattern 116 may include silicon oxide, silicon nitride, or a combination thereof.

The channel structure CHST may include a plurality of gate dielectric layers 122 respectively interposed between the plurality of word lines WL and the plurality of channel patterns CHL adjacent to the plurality of word lines WL. A pair of gate dielectric layers 122 may be arranged between a pair of channel patterns CHL that are spaced apart from each other with the separation insulating pattern 124 therebetween and are adjacent to each other in the first horizontal direction (X direction). A pair of word lines WL may be arranged between the pair of gate dielectric layers 122. Each of the pair of gate dielectric layers 122 may be interposed between one word line WL and channel patterns CHL disposed adjacent to the one word line WL and arranged in the second horizontal direction (Y direction) among the plurality of channel patterns CHL, and may be in contact with the word line WL and the channel patterns CHL.

According to some example embodiments, one sidewall of each of the plurality of channel patterns CHL in the first horizontal direction (X direction) may be in contact with one selected from the plurality of back gate dielectric layers 112, and the other sidewall thereof may be in contact with one selected from the plurality of gate dielectric layers 122. According to some example embodiments, each of both sidewalls of each of the plurality of channel patterns CHL in the second horizontal direction (Y direction) may be in contact with a corresponding gate dielectric layer 122 among the plurality of gate dielectric layers 122, and may face a corresponding word line WL among the plurality of word lines WL with the gate dielectric layer 122 interposed therebetween.

According to some example embodiments, the separation insulating pattern 124 may be disposed between a pair of word lines WL arranged between a pair of adjacent channel patterns CHL. A first buried insulating pattern 126 may be disposed between a pair of word lines WL and a bit line BL, and a second buried insulating pattern 128 may be disposed between a word line WL and a plurality of contact plugs 130. A pair of second buried insulating patterns 128 may be spaced apart from each other in the first horizontal direction (X direction) with a separation insulating pattern 124 therebetween. The first buried insulating pattern 126, the pair of word lines WL, and the pair of second buried insulating patterns 128 may be arranged to overlap each other in the vertical direction (Z direction), between the pair of adjacent channel patterns CHL. The pair of word lines WL and the separation insulating pattern 124 may be spaced apart from the plurality of bit lines BL in the vertical direction (Z direction) with the first buried insulating pattern 126 therebetween. The pair of word lines WL may be spaced apart from the plurality of contact plugs 130 in the vertical direction (Z direction) with the second buried insulating pattern 128 therebetween. According to some example embodiments, each of the separation insulating pattern 124, the first buried insulating pattern 126, and the second buried insulating pattern 128 may include silicon oxide, silicon nitride, or a combination thereof.

According to some example embodiments, each of the gate dielectric layer 122 and the back gate dielectric layer 112 may include a silicon oxide layer, a high-k dielectric layer, or a combination thereof. The term “high-k dielectric layer” refers to a dielectric layer having a higher dielectric constant than silicon oxide. According to some example embodiments, each of the gate dielectric layer 122 and the back gate dielectric layer 112 may include at least one selected from silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO). A plurality of back gate electrodes BG, a plurality of word lines WL, a plurality of channel patterns CHL, a plurality of back gate dielectric layers 112, and a plurality of gate dielectric layers 122 arranged between a plurality of bit lines BL and a plurality of contact plugs 130 may constitute a plurality of vertical channel transistors CTR. The plurality of vertical channel transistors CTR used herein may be referred to as a vertical channel transistor structure.

In FIG. 20, upper surfaces of the plurality of back gate electrodes BG are illustrated as being arranged closer to the plurality of bit lines BL than upper surfaces of the plurality of word lines WL are. However, the technical idea of the inventive concepts is not limited thereto. For example, the upper surfaces of the plurality of back gate electrodes BG may be arranged on the same vertical level as the upper surfaces of the plurality of word lines WL or may be arranged farther away from the plurality of bit lines BL than the upper surfaces of the plurality of word lines WL are.

The bit line structure BLST may include the plurality of bit lines BL, and an interlayer insulating layer OBL surrounding the plurality of bit lines BL. According to some example embodiments, the plurality of bit lines BL may each extend in the first horizontal direction (X direction) and may be repeatedly arranged to be apart from each other in the second horizontal direction (Y direction) orthogonal to the first horizontal direction (X direction). According to some example embodiments, the plurality of bit lines BL may be spaced apart from each other in the second horizontal direction (Y direction) with the interlayer insulating layer OBL therebetween. The interlayer insulating layer OBL may completely fill a space between the plurality of bit lines BL and may cover tops of the plurality of bit lines BL. According to some example embodiments, a plurality of insulating capping lines BLCP may cover the upper surfaces of the plurality of bit lines BL, and the interlayer insulating layer OBL may fill both the space between the plurality of bit lines BL and a space between a plurality of insulating capping lines BLCP and may cover tops of the plurality of insulating capping lines BLCP. According to some example embodiments, each of the plurality of bit lines BL may have a stacked structure of a first line pattern, a second line pattern, and a third line pattern. For example, the first line pattern may include a semiconductor material, and each of the second line pattern and the third line pattern may include a metal-based material. The second line pattern and the third line pattern may include different types of metal-based materials. For example, the first line pattern may include doped polysilicon. For example, the second line pattern may include TiN or Ti—Si—N (TSN), and the third line pattern may include tungsten (W) or may include W and tungsten silicide (WSiₓ). According to some example embodiments, the second line pattern may function as a diffusion barrier. A insulating capping line BLCP may be disposed on the third line pattern. The first line pattern, the second line pattern, the third line pattern, and the insulating capping line BLCP may be sequentially arranged on the channel patterns CHL. The interlayer insulating layer OBL may include silicon oxide, silicon nitride, or a combination thereof. Each of the plurality of insulating capping lines BLCP may include silicon nitride.

The peripheral circuit structure PRST includes a peripheral circuit device layer PFEOL and a peripheral circuit wiring layer PBEOL on the peripheral circuit device layer PFEOL. The peripheral circuit device layer PFEOL may include a peripheral circuit substrate 202 having a plurality of active regions AC defined by a circuit device isolation layer 204, a plurality of circuit gate structures 210 arranged in the plurality of active regions AC of the peripheral circuit substrate 202, a circuit interlayer insulating layer 220 covering the peripheral circuit substrate 202 and the plurality of circuit gate structures 210 below the peripheral circuit substrate 202, and a peripheral circuit connection structure 230 surrounded by the circuit interlayer insulating layer 220 and electrically connected to the plurality of active regions AC and/or the plurality of circuit gate structures 210. A plurality of circuit gate structures 210 arranged below the plurality of active regions AC may constitute a plurality of peripheral circuit transistors PTR.

The peripheral circuit substrate 202 may have a peripheral circuit active surface PSBA and a peripheral circuit inactive surface PSBI that are opposite to each other. The peripheral circuit active surface PSBA of the peripheral circuit substrate 202 may face the cell array structure CST. The peripheral circuit substrate 202 may include, for example, a semiconductor material such as a Group IV semiconductor material, a Groups III and V semiconductor material, a Groups II and VI semiconductor material, or a Groups II and VI oxide semiconductor material. The Group IV semiconductor material may include, for example, silicon (Si), germanium (Ge), or Si—Ge. The Groups III and V semiconductor material may include, for example, gallium arsenide (GaAs), indium phosphorus (InP), gallium phosphorus (GaP), indium arsenide (InAs), indium antimony (InSb), or indium gallium arsenide (InGaAs). The Groups II and VI semiconductor material may include, for example, zinc telluride (ZnTe) or cadmium sulfide (CdS). The peripheral circuit substrate 202 may be a bulky wafer or an epitaxial layer. The peripheral circuit substrate 202 may be provided as a bulky wafer or an epitaxial layer. The peripheral circuit substrate 202 may be any one of the peripheral circuit substrates PSUB shown in FIG. 10A, FIG. 11A, FIG. 12A, FIG. 13A, FIG. 14A, FIG. 15A, FIG. 15B, FIG. 16A, FIG. 16B, and FIG. 16C. For example, the peripheral circuit substrate 202 includes the front P-wells PWF, the front N-wells NWF, and the back P-wells PWB shown in FIG. 10A, FIG. 11A, FIG. 12A, FIG. 13A, FIG. 14A, FIG. 15A, FIG. 15B, FIG. 16A, FIG. 16B, and FIG. 16C. According to some example embodiments, the peripheral circuit substrate 202 may further include the deep front N-well DNWF shown in FIGS. 10A, 11A, 12A, 13A, and 14A, or may further include the back N-well NWB shown in FIGS. 11A, 12A, 13A, 14A, 15A, 15B, 16A, 16B, and 16C.

An active region AC may be defined by a circuit device isolation layer 204 in the peripheral circuit substrate 202, and the active region AC and the circuit gate structure 210 may constitute the peripheral circuit transistor PTR. The circuit gate structure 210 may include a circuit gate electrode 214 below the active region AC, a circuit gate insulating layer 212 interposed between the active region AC and the circuit gate electrode 214, a circuit gate capping layer 216 covering a lower surface of the circuit gate electrode 214, and a circuit gate spacer 218 covering lateral surfaces of the circuit gate insulating layer 212, the circuit gate electrode 214, and the circuit gate capping layer 216.

The peripheral circuit connection structure 230 may include a circuit connection line and a circuit connection contact. The peripheral circuit connection structure 230 may include a conductive material such as copper (Cu), aluminum (Al), tungsten (W), silver (Ag), gold (Au), or a combination thereof. The circuit interlayer insulating layer 220 may include an insulating material that may include silicon oxide, silicon nitride, a low-k dielectric material, or a combination thereof. The low-k dielectric material is a material having a lower dielectric constant than silicon oxide, and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. According to some example embodiments, the circuit interlayer insulating layer 220 may include an ultra low k (ULK) layer having an ultra low dielectric constant K of about 2.2 to about 2.4. The ULK layer may include SiOC or SiCOH.

The peripheral circuit wiring layer PBEOL may include a circuit wiring insulating layer 240 covering the peripheral circuit inactive surface PSBI of the peripheral circuit substrate 202, a circuit wiring structure 250 surrounded by the circuit wiring insulating layer 240, and a peripheral circuit capping layer PRCP covering the circuit wiring insulating layer 240 and the circuit wiring structure 250. The peripheral circuit capping layer PRCP may include silicon oxide, silicon nitride, or a combination thereof.

The peripheral circuit structure PRST may include a peripheral circuit connection via PCV interposed between the peripheral circuit connection structure 230 and the circuit wiring structure 250 and extending in the vertical direction (Z direction). The peripheral circuit connection via PCV may electrically connect the peripheral circuit connection structure 230 to the circuit wiring structure 250. The peripheral circuit connection via PCV may pass through the circuit wiring insulating layer 240, the circuit device isolation layer 204, and the circuit interlayer insulating layer 220. The peripheral circuit connection via PCV may extend from the peripheral circuit structure PRST toward the cell array structure CST and may have a tapered shape in which a horizontal width gradually decreases. For example, the peripheral circuit connection via PCV may have a tapered shape in which a horizontal width gradually decreases and extends from the circuit wiring structure 250 to the peripheral circuit connection structure 230. According to some example embodiments, the peripheral circuit structure PRST may further include a peripheral circuit via insulating layer PCI surrounding a lateral surface of the peripheral circuit connection via PCV.

The bonding structure BDST may be interposed between the cell array structure CST and the peripheral circuit structure PRST. The bonding structure BDST may include a plurality of cell bonding pads BDCP arranged on the cell array structure CST, a first bonding insulating layer 166 disposed on the cell array structure CST and surrounding the plurality of cell bonding pads BDCP, a plurality of peripheral circuit bonding pads BDPP arranged below the peripheral circuit structure PRST, and a second bonding insulating layer 266 disposed below the peripheral circuit structure PRST and surrounding the plurality of peripheral circuit bonding pads BDPP. Upper surfaces of the plurality of cell bonding pads BDCP and an upper surface of the first bonding insulating layer 166 may form a coplanar surface. Lower surfaces of the plurality of cell bonding pads BDCP and a lower surface of the second bonding insulating layer 266 may form a coplanar surface. The first bonding insulating layer 166 may cover an upper surface of the cell array structure CST. For example, the first bonding insulating layer 166 may cover an upper surface of the interlayer insulating layer OBL. The second bonding insulating layer 266 may cover a lower surface of the peripheral circuit structure PRST. According to some example embodiments, the second bonding insulating layer 266 may cover a lower surface of the circuit interlayer insulating layer 220.

The cell bonding via CCV extending in the vertical direction (Z direction) may be interposed between the cell bonding pad BDCP and the bit line BL. Although FIG. 20 illustrates that the cell bonding via CCV electrically connects the cell bonding pad BDCP to the bit line BL, some example embodiments are not limited thereto. For example, the cell bonding via CCV may electrically connect between the cell bonding pad BDCP and the word line WL, between the cell bonding pad BDCP and the back gate electrode BG, and/or between the cell bonding pad BDCP and the upper electrode 156. According to some example embodiments, the peripheral circuit connection via PCV may electrically connect the peripheral circuit connection structure 230 to the peripheral circuit bonding pad BDPP, or electrically connect the circuit wiring structure 250 to the peripheral circuit bonding pad BDPP.

The peripheral circuit structure PRST may be bonded onto the cell array structure CST through the plurality of cell bonding pads BDCP, the plurality of peripheral circuit bonding pads BDPP, the first bonding insulating layer 166, and the second bonding insulating layer 266 included in the bonding structure BDST. According to some example embodiments, the cell array structure CST and the peripheral circuit structure PRST may be bonded to each other in a hybrid bonding manner. For example, the first bonding insulating layer 166 and the second bonding insulating layer 266 may be bonded to each other by forming a covalent bond, and a cell bonding pad BDCP and a peripheral circuit bonding pad BDPP corresponding to each other may face each other and then be expanded by heat and come into contact with each other, and may be combined with each other by diffusion bonding so as to be integrally formed through diffusion of metal atoms included therein. Each of the cell bonding pad BDCP and the peripheral circuit bonding pad BDPP may include a material containing copper (Cu). Each of the first bonding insulating layer 166 and the second bonding insulating layer 266 may include silicon oxide or silicon carbon nitride (SiCN).

Referring to FIG. 21, the semiconductor device 1004a may include the cell array structure CST in which a plurality of memory cells are arranged, and the peripheral circuit structure PRST stacked on the cell array structure CST. The cell array structure CST may include a bit line structure BLST, a channel structure CHST, and a capacitor structure CTST that are sequentially stacked in the vertical direction (Z direction). The peripheral circuit structure PRST, the bit line structure BLST, the channel structure CHST, and the capacitor structure CTST shown in FIG. 21 may be the same or substantially the same as the peripheral circuit structure PRST, the bit line structure BLST, the channel structure CHST, and the capacitor structure CTST shown in FIG. 20, but the bit line structure BLST, the channel structure CHST, and the capacitor structure CTST shown in FIG. 21 may have a structure in which the bit line structure BLST, the channel structure CHST, and the capacitor structure CTST shown in FIG. 20 are turned upside down, and any other overlapping description may be omitted.

The bit line structure BLST may completely fill a space between the plurality of bit lines BL, and may include the interlayer insulating layer OBL covering bottoms of the plurality of bit lines BL. According to some example embodiments, the interlayer insulating layer OBL may function as a bonding insulating layer for bonding the support substrate 102 to the bit line structure BLST. For example, after the bit line structure BLST is formed, the bit line structure BLST may be attached onto the support substrate 102 such that the interlayer insulating layer OBL of the bit line structure BLST faces the support substrate 102.

The cell bonding via CCV extending in the vertical direction (Z direction) may be interposed between the cell bonding pad BDCP and the upper electrode 156. Although FIG. 21 illustrates that the cell bonding via CCV electrically connects the cell bonding pad BDCP to the upper electrode 156, some example embodiments are not limited thereto. For example, the cell bonding via CCV may electrically connect between the cell bonding pad BDCP and the word line WL, between the cell bonding pad BDCP and the back gate electrode BG, and/or between the cell bonding pad BDCP and the bit line BL.

FIG. 22 is a schematic perspective view of the semiconductor device 1000b according to some example embodiments.

Referring to FIG. 22, the semiconductor device 1000b may include a cell array structure CST and a peripheral circuit structure PRST. The peripheral circuit structure PRST and the cell array structure CST shown in FIG. 22 are the same or substantially the same as the peripheral circuit structure PRST and the cell array structure CST shown in FIG. 2, and thus, any duplicate description may be omitted. The peripheral circuit structure PRST shown in FIG. 22 is depicted as including a portion of the peripheral circuit structure PRST of FIG. 2 that corresponds to the peripheral circuit device layer PFEOL, but may further include the peripheral circuit wiring layer PBEOL shown in FIG. 2. The bonding structure BDST of FIG. 2 may be interposed between the cell array structure CST and the peripheral circuit structure PRST included in the semiconductor device 1000b of FIG. 22.

The cell array structure CST may include a plurality of memory cells MC arranged in a 2D or 3D manner. Each of the plurality of memory cells MC may be connected between a word line WL and a bit line BL that intersect each other. Each of the plurality of memory cells MC may include a selection element TR and a data storage element DS, and the selection element TR and the data storage element DS may be electrically connected to each other in series. The selection element TR may be connected between the data storage element DS and the word line WL, and the data storage element DS may be connected to the bit line BL through the selection element TR.

The peripheral circuit structure PRST may be bonded onto the cell array structure CST. In the semiconductor device 1000b, the peripheral circuit structure PRST and the cell array structure CST may be bonded to each other by using a metal-oxide hybrid bonding method or a direct bonding method. The peripheral circuit structure PRST may include the peripheral circuit substrate PSUB. The peripheral circuit substrate PSUB may have a peripheral circuit active surface PSBA and a peripheral circuit inactive surface PSBI that are opposite to each other. The peripheral circuit structure PRST may be bonded onto the cell array structure CST such that the peripheral circuit inactive surface PSBI of the peripheral circuit substrate PSUB faces the cell array structure CST in the vertical direction (Z direction).

FIGS. 23 and 24 are cross-sectional views of the semiconductor devices 1002b and 1004b according to some example embodiments.

Referring to FIG. 23, the semiconductor device 1002b may include a cell array structure CST in which a plurality of memory cells are arranged, and a peripheral circuit structure PRST stacked on the cell array structure CST. The cell array structure CST may include a capacitor structure CTST, a channel structure CHST, and a bit line structure BLST that are sequentially stacked in the vertical direction (Z direction). The peripheral circuit structure PRST includes a peripheral circuit device layer PFEOL and a peripheral circuit wiring layer PBEOL on the peripheral circuit device layer PFEOL. The peripheral circuit structure PRST, the capacitor structure CTST, the channel structure CHST, and the bit line structure BLST shown in FIG. 23 may be the same or substantially the same as the peripheral circuit structure PRST, the capacitor structure CTST, the channel structure CHST, and the bit line structure BLST shown in FIG. 20, but the peripheral circuit device layer PFEOL of the peripheral circuit structure PRST shown in FIG. 23 may have a structure in which the peripheral circuit device layer PFEOL of the peripheral circuit structure PRST shown in FIG. 20 is turned upside down, and any other overlapping description may be omitted.

The bonding structure BDST may be interposed between the cell array structure CST and the peripheral circuit structure PRST. The bonding structure BDST may include a first bonding insulating layer 166 disposed above the cell array structure CST and a second bonding insulating layer 266 disposed below the peripheral circuit structure PRST. The peripheral circuit structure PRST may be bonded onto the cell array structure CST through the first bonding insulating layer 166 and the second bonding insulating layer 266 included in the bonding structure BDST. For example, the first bonding insulating layer 166 and the second bonding insulating layer 266 may be bonded to each other by forming a covalent bond. The cell array structure CST and the peripheral circuit structure PRST may be bonded to each other in a direct bonding manner. Each of the first bonding insulating layer 166 and the second bonding insulating layer 266 may include silicon oxide or silicon carbon nitride (SiCN).

The bonding structure BDST may include a peripheral circuit connection via PCV interposed between the peripheral circuit connection structure 230 and the bit line BL and extending in the vertical direction (Z direction). The peripheral circuit connection via PCV may electrically connect the peripheral circuit connection structure 230 to the bit line BL. The peripheral circuit connection via PCV may pass through the circuit interlayer insulating layer 220, the circuit device isolation layer 204, the peripheral circuit substrate 202, the second bonding insulating layer 266, the first bonding insulating layer 166, the interlayer insulating layer OBL, and the insulating capping line BLCP. The peripheral circuit connection via PCV may extend from the peripheral circuit structure PRST toward the cell array structure CST and may have a tapered shape in which a horizontal width gradually decreases. For example, the peripheral circuit connection via PCV may have a tapered shape in which a horizontal width gradually decreases and extends from the peripheral circuit connection structure 230 to the bit line BL. According to some example embodiments, the peripheral circuit structure PRST may further include a peripheral circuit via insulating layer PCI surrounding a lateral surface of the peripheral circuit connection via PCV. Although FIG. 23 illustrates that the peripheral circuit connection via PCV electrically connects the peripheral circuit connection structure 230 to the bit line BL, some example embodiments are not limited thereto. For example, the peripheral circuit connection via PCV may electrically connect between the peripheral circuit connection structure 230 and the word line WL, between the peripheral circuit connection structure 230 and the back gate electrode BG, and/or between the peripheral circuit connection structure 230 and the upper electrode 156.

Referring to FIG. 24, the semiconductor device 1004b may include a cell array structure CST in which a plurality of memory cells are arranged, and a peripheral circuit structure PRST stacked on the cell array structure CST. The cell array structure CST may include a bit line structure BLST, a channel structure CHST, and a capacitor structure CTST that are sequentially stacked in the vertical direction (Z direction). The peripheral circuit structure PRST shown in FIG. 24 may be the same or substantially the same as the peripheral circuit structure PRST shown in FIG. 23, but the bit line structure BLST, the channel structure CHST, and the capacitor structure CTST shown in FIG. 24 may be the same or substantially the same as the bit line structure BLST, the channel structure CHST, and the capacitor structure CTST shown in FIG. 21, and thus redundant descriptions thereof may be omitted.

The bonding structure BDST may be interposed between the cell array structure CST and the peripheral circuit structure PRST. The bonding structure BDST may include a first bonding insulating layer 166 disposed above the cell array structure CST and a second bonding insulating layer 266 disposed below the peripheral circuit structure PRST. The peripheral circuit structure PRST may be bonded onto the cell array structure CST through the first bonding insulating layer 166 and the second bonding insulating layer 266 included in the bonding structure BDST. For example, the first bonding insulating layer 166 and the second bonding insulating layer 266 may be bonded to each other by forming a covalent bond. The cell array structure CST and the peripheral circuit structure PRST may be bonded to each other in a direct bonding manner. Each of the first bonding insulating layer 166 and the second bonding insulating layer 266 may include silicon oxide or silicon carbon nitride (SiCN).

The bonding structure BDST may include a peripheral circuit connection via PCV interposed between the peripheral circuit connection structure 230 and the upper electrode 156 and extending in the vertical direction (Z direction). The peripheral circuit connection via PCV may electrically connect the peripheral circuit connection structure 230 to the upper electrode 156. The peripheral circuit connection via PCV may pass through the circuit interlayer insulating layer 220, the circuit device isolation layer 204, the peripheral circuit substrate 202, the second bonding insulating layer 266, the first bonding insulating layer 166, and the capacitor capping layer CTCP. The peripheral circuit connection via PCV may extend from the peripheral circuit structure PRST toward the cell array structure CST and may have a tapered shape in which a horizontal width gradually decreases. For example, the peripheral circuit connection via PCV may have a tapered shape in which a horizontal width gradually decreases and extends from the peripheral circuit connection structure 230 to the upper electrode 156. According to some example embodiments, the peripheral circuit structure PRST may further include a peripheral circuit via insulating layer PCI surrounding a lateral surface of the peripheral circuit connection via PCV. Although FIG. 24 illustrates that the peripheral circuit connection via PCV electrically connects the peripheral circuit connection structure 230 to the upper electrode 156, some example embodiments are not limited thereto. For example, the peripheral circuit connection via PCV may electrically connect between the peripheral circuit connection structure 230 and the word line WL, between the peripheral circuit connection structure 230 and the back gate electrode BG, and/or between the peripheral circuit connection structure 230 and the bit line BL.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

Some example embodiments of the inventive concepts still further provide a method of manufacturing a semiconductor device, the method including preparing a cell array structure in which a plurality of cells are arranged; forming a peripheral circuit structure by forming a plurality of peripheral circuit transistors arranged on a peripheral circuit substrate having a peripheral circuit active surface and a peripheral circuit inactive surface opposite to each other along the peripheral circuit active surface; and bonding the peripheral circuit structure onto the cell array structure. The forming of the peripheral circuit structure includes preparing a preliminary peripheral circuit substrate having a front surface and a back surface opposite to each other; forming a front P-well and a front N-well each extending from the front surface of the preliminary peripheral circuit substrate into the peripheral circuit substrate; forming the peripheral circuit substrate having the peripheral circuit active surface, which is a front surface of the preliminary peripheral circuit substrate, and the peripheral circuit inactive surface, by removing a portion of the preliminary peripheral circuit substrate from a back surface of the preliminary peripheral circuit substrate; and forming a back P-well extending from the peripheral circuit inactive surface into the peripheral circuit substrate and overlapping the front P-well. A doping profile of the back P-well decreases toward the peripheral circuit active surface from a peak of a dopant concentration of the back P-well which is adjacent to the peripheral circuit inactive surface but is located apart from the peripheral circuit inactive surface in the vertical direction.

According to some example embodiments, the forming of the back P-well may include forming the back P-well so that a value of the peak of the dopant concentration of the back P-well is greater than a value of a peak of a dopant concentration of the front P-well.

According to some example embodiments, the forming of the back P-well may include forming the back P-well to have a doping profile in which a rate of decrease toward the peripheral circuit inactive surface from the peak of the dopant concentration of the back P-well is greater than a rate of decrease toward the peripheral circuit active surface from the peak of the dopant concentration of the back P-well.

According to some example embodiments, the forming of the back P-well may include forming the back P-well so that a depth of the peak of the dopant concentration of the back P-well from the peripheral circuit inactive surface is less than a depth of the peak of the dopant concentration of the front P-well from the peripheral circuit active surface.

According to some example embodiments, the forming of the peripheral circuit structure may further include forming a back N-well extending from the peripheral circuit inactive surface into the peripheral circuit substrate, a doping profile of the back N-well may decrease toward the peripheral circuit active surface from a peak of a dopant concentration of the back N-well which is located adjacent to the peripheral circuit inactive surface, and the back N-well may be formed such that the front N-well overlaps the back N-well in the vertical direction.

According to some example embodiments, the forming of the back N-well may include forming the back N-well so that a value of the peak of the dopant concentration of the back N-well is greater than a value of a peak of a dopant concentration of the front N-well.

According to some example embodiments, the forming of the back N-well may include forming the back N-well to have a doping profile in which a rate of decrease toward the peripheral circuit inactive surface from the peak of the dopant concentration of the back N-well is greater than a rate of decrease toward the peripheral circuit active surface from the peak of the dopant concentration of the back N-well.

According to some example embodiments, the forming of the back N-well may include forming the back N-well so that a depth of the peak of the dopant concentration of the back N-well from the peripheral circuit inactive surface is less than a depth of the peak of the dopant concentration of the front N-well from the peripheral circuit active surface.

According to some example embodiments, the forming of the peripheral circuit structure may further include forming a deep front N-well extending from the front surface of the preliminary peripheral circuit substrate into the peripheral circuit substrate, and the forming of the back N-well may include forming the back N-well such that the back N-well does not overlap the deep front N-well.

According to some example embodiments, in the forming of the front P-well and the front N-well, the front P-well may include front P-wells that are spaced apart from each other, the front N-well may include front N-wells that are spaced apart from each other, and some of the front P-wells and some of the front N-wells may be formed within the deep N-well.

Some example embodiments of the inventive concepts still also further provide a method of manufacturing a semiconductor device that includes forming a cell array structure including a plurality of memory cells; forming a peripheral circuit structure including a peripheral circuit substrate having a peripheral circuit active surface and a peripheral circuit inactive surface opposite to each other, and a plurality of peripheral circuit transistors along the peripheral circuit active surface; and bonding the cell array to the peripheral circuit structure. The forming the peripheral circuit structure includes implanting a front P-well extending from the peripheral circuit active surface into the peripheral circuit substrate; implanting a front N-well extending from the peripheral circuit active surface into the peripheral circuit substrate; implanting a back P-well extending from the peripheral circuit inactive surface into the peripheral circuit substrate, the back P-well overlapping the front P-well in a vertical direction; and implanting a back N-well extending from the peripheral circuit inactive surface into the peripheral circuit substrate, the back N-well overlapping the front N-well in the vertical direction.

According to some example embodiments, the implanting the back P-well includes providing a doping profile of the back P-well as decreasing toward the peripheral circuit active surface from a peak of a dopant concentration of the back P-well, the peak of the dopant concentration of the back P-well being adjacent to and spaced apart from the peripheral circuit inactive surface in the vertical direction; and the implanting the back N-well includes providing a doping profile of the back N-well as decreasing toward the peripheral circuit active surface from a peak of a dopant concentration of the back N-well, the peak of the dopant concentration of the back N-well being adjacent to and spaced apart from the peripheral circuit inactive surface in the vertical direction.

According to some example embodiments, the implanting the back P-well includes providing the doping profile of the back P-well as decreasing toward the peripheral circuit inactive surface from the peak of the dopant concentration of the back P-well at a first rate and as decreasing toward the peripheral circuit active surface from the peak of the dopant concentration of the back P-well at a second rate, the first rate being greater than the second rate; and the implanting the back N-well includes providing the doping profile of the back N-well as decreasing toward the peripheral circuit inactive surface from the peak of the dopant concentration of the back N-well at a third rate and as decreasing toward the peripheral circuit active surface from the peak of the dopant concentration of the back N-well at a fourth rate, the third rate being greater than the fourth rate.

According to some example embodiments, a value of the peak of the dopant concentration of the back P-well is greater than a value of a peak of a dopant concentration of the front P-well, and a value of the peak of the dopant concentration of the back N-well is greater than a value of a peak of a dopant concentration of the front N-well.

According to some example embodiments, the forming the peripheral circuit structure further includes implanting a deep N-well between and overlapping the back P-well and the front P-well.

According to some example embodiments, a depth of the peak of the dopant concentration of the back P-well from the peripheral circuit inactive surface is less than a depth of a peak of a dopant concentration of the front P-well from the peripheral circuit active surface.

According to some example embodiments, a value of the peak of the dopant concentration of the back P-well is greater than a value of a peak of a dopant concentration of the front P-well.

According to some example embodiments, a value of the peak of the dopant concentration of the back N-well is greater than a value of a peak of a dopant concentration of the front N-well.

According to some example embodiments, a depth of the peak of the dopant concentration of the back N-well from the peripheral circuit inactive surface is less than a depth of a peak of a dopant concentration of the front N-well from the peripheral circuit active surface.

According to some example embodiments, the bonding the cell array to the peripheral circuit structure includes providing the peripheral circuit active surface as facing the cell array structure.

According to some example embodiments, the bonding the cell array to the peripheral circuit structure includes providing the peripheral circuit inactive surface as facing the cell array structure.

While the inventive concepts has been particularly shown and described with reference to some example embodiments thereof, it will be understood that various changes in form and details may be made therein without departing from the spirit and scope of the following claims.

What is claimed is:

1. A semiconductor device comprising:
a cell array structure including a plurality of cells; and
a peripheral circuit structure on the cell array structure, the peripheral circuit structure comprising a peripheral circuit substrate having a peripheral circuit active surface and a peripheral circuit inactive surface opposite to each other,
wherein the peripheral circuit substrate includes a front P-well and a front N-well each extending from the peripheral circuit active surface into the peripheral circuit substrate, and a back P-well extending from the peripheral circuit inactive surface into the peripheral circuit substrate and overlapping the front P-well in a vertical direction, and
a doping profile of the back P-well decreases toward the peripheral circuit active surface from a peak of a dopant concentration of the back P-well that is adjacent to the peripheral circuit inactive surface and that is spaced apart from the peripheral circuit inactive surface in the vertical direction.

2. The semiconductor device of claim 1, wherein a rate that the doping profile of the back P-well decreases toward the peripheral circuit inactive surface from the peak of the dopant concentration of the back P-well is greater than a rate that the doping profile of the back P-well decreases toward the peripheral circuit active surface from the peak of the dopant concentration of the back P-well.

3. The semiconductor device of claim 1, wherein a depth of the peak of the dopant concentration of the back P-well from the peripheral circuit inactive surface is less than a depth of a peak of a dopant concentration of the front P-well from the peripheral circuit active surface.

4. The semiconductor device of claim 1, wherein a value of the peak of the dopant concentration of the back P-well is greater than a value of a peak of a dopant concentration of the front P-well.

5. The semiconductor device of claim 4, wherein
the peripheral circuit substrate further includes a back N-well extending from the peripheral circuit inactive surface into the peripheral circuit substrate,
the front N-well overlaps the back N-well in the vertical direction, and
a doping profile of the back N-well decreases toward the peripheral circuit active surface from a peak of a dopant concentration of the back N-well that is adjacent to the peripheral circuit inactive surface.

6. The semiconductor device of claim 5, wherein a value of the peak of the dopant concentration of the back N-well is greater than a value of a peak of a dopant concentration of the front N-well.

7. The semiconductor device of claim 5, wherein a rate at which the doping profile of the back N-well decreases toward the peripheral circuit inactive surface from the peak of the dopant concentration of the back N-well is greater than a rate at which the doping profile of the back N-well decreases toward the peripheral circuit active surface from the peak of the dopant concentration of the back N-well.

8. The semiconductor device of claim 5, wherein
a depth of the peak of the dopant concentration of the back N-well from the peripheral circuit inactive surface is less than a depth of a peak of a dopant concentration of the front N-well from the peripheral circuit active surface.

9. The semiconductor device of claim 5, wherein
the peripheral circuit substrate has a first well region and a second well region,
the peripheral circuit substrate includes a deep front N-well extending from the peripheral circuit active surface into the first well region of the peripheral circuit substrate, and
the back N-well does not overlap the deep front N-well.

10. The semiconductor device of claim 1, wherein the cell array structure comprises:
a bit line extending in a first horizontal direction;
a contact plug extending in the vertical direction;
a channel pattern between the bit line and one end of the contact plug, the channel pattern extending in the vertical direction;
a word line adjacent to the channel pattern between the bit line and the one end of the contact plug, the word line extending in a second horizontal direction orthogonal to the first horizontal direction; and
a capacitor including a lower electrode connected to another end of the contact plug, a capacitor dielectric layer covering the lower electrode, and an upper electrode covering the capacitor dielectric layer.

11. A semiconductor device comprising:
a cell array structure including a plurality of memory cells comprised of a plurality of semiconductor patterns, a plurality of word lines adjacent to the plurality of semiconductor patterns, a plurality of bit lines connected to the plurality of semiconductor patterns, and a plurality of information storage elements connected to the plurality of semiconductor patterns;
a peripheral circuit structure including a peripheral circuit substrate having a peripheral circuit active surface and a peripheral circuit inactive surface opposite to each other, and a plurality of peripheral circuit transistors along the peripheral circuit active surface, the peripheral circuit substrate being stacked on the cell array structure; and
a bonding structure between the cell array structure and the peripheral circuit structure, the bonding structure configured to bond the cell array structure to the peripheral circuit structure,
wherein
the peripheral circuit substrate includes a front P-well and a front N-well each extending from the peripheral circuit active surface into the peripheral circuit substrate, and a back P-well and a back N-well each extending from the peripheral circuit inactive surface into the peripheral circuit substrate,
a doping profile of the back P-well decreases toward the peripheral circuit active surface from a peak of dopant concentration of the back P-well, the peak of the dopant concentration of the back P-well being adjacent to and spaced apart from the peripheral circuit inactive surface in a vertical direction, and
a doping profile of the back N-well decreases toward the peripheral circuit active surface from a peak of a dopant concentration of the back N-well, the peak of the dopant concentration of the back N-well being adjacent to and spaced apart from the peripheral circuit inactive surface in the vertical direction.

12. The semiconductor device of claim 11, wherein
a rate that the doping profile of the back P-well decreases toward the peripheral circuit inactive surface from the peak of the dopant concentration of the back P-well is greater than a rate that the doping profile of the back P-well decreases toward the peripheral circuit active surface from the peak of the dopant concentration of the back P-well, and
a rate that the doping profile of the back N-well decreases toward the peripheral circuit inactive surface from the peak of the dopant concentration of the back N-well is greater than a rate that the doping profile of the back N-well decreases toward the peripheral circuit active surface from the peak of the dopant concentration of the back N-well.

13. The semiconductor device of claim 11, wherein
a value of the peak of the dopant concentration of the back P-well is greater than a value of a peak of a dopant concentration of the front P-well, and
a value of the peak of the dopant concentration of the back N-well is greater than a value of a peak of a dopant concentration of the front N-well.

14. The semiconductor device of claim 11, wherein, in the vertical direction, the front P-well overlaps the back P-well, and the front N-well overlaps the back N-well.

15. The semiconductor device of claim 11, wherein
the cell array structure further includes a plurality of contact plugs each extending in the vertical direction,
respective first ends of the plurality of contact plugs are connected to the plurality of semiconductor patterns, and respective other ends of the plurality of contact plugs are connected to the plurality of information storage elements,
each of the plurality of bit lines extend in a first horizontal direction,
each of the plurality of semiconductor patterns extend in the vertical direction, and
each of the plurality of word lines extend in a second horizontal direction orthogonal to the first horizontal direction.

16. The semiconductor device of claim 11, wherein the peripheral circuit active surface of the peripheral circuit substrate faces the cell array structure.

17. The semiconductor device of claim 11, wherein the peripheral circuit inactive surface of the peripheral circuit substrate faces the cell array structure.

18. A semiconductor device comprising:
a cell array structure including
a plurality of bit lines each extending in a first horizontal direction, a plurality of contact plugs each extending in a vertical direction,
a plurality of channel patterns each extending in the vertical direction between the plurality of bit lines and respective first ends of the plurality of contact plugs,
a plurality of word lines and a plurality of back gate electrodes each extending in a second horizontal direction orthogonal to the first horizontal direction and between the plurality of bit lines and the respective first ends of the plurality of contact plugs, the plurality of word lines and the plurality of back gate electrodes being spaced apart from each other with the plurality of channel patterns between the plurality of word lines and the plurality of back gate electrodes, and
a plurality of capacitors including a plurality of lower electrodes connected to respective other ends of the plurality of contact plugs, a capacitor dielectric layer covering the plurality of lower electrodes, and an upper electrode covering the capacitor dielectric layer;
a peripheral circuit structure including a peripheral circuit substrate having a peripheral circuit active surface and a peripheral circuit inactive surface opposite to each other, and a plurality of peripheral circuit transistors along the peripheral circuit active surface, the peripheral circuit substrate being stacked on the cell array structure; and
a bonding structure between the cell array structure and the peripheral circuit structure, the bonding structure configured to bond the cell array structure to the peripheral circuit structure,
wherein
the peripheral circuit substrate includes a front P-well and a front N-well each extending from the peripheral circuit active surface into the peripheral circuit substrate, a back P-well extending from the peripheral circuit inactive surface into the peripheral circuit substrate and overlapping the front P-well in the vertical direction, and a back N-well extending from the peripheral circuit inactive surface into the peripheral circuit substrate and overlapping the front N-well in the vertical direction,
a doping profile of the back P-well decreases toward the peripheral circuit active surface from a peak of dopant concentration of the back P-well, the peak of the dopant concentration of the back P-well being adjacent to and spaced apart from the peripheral circuit inactive surface in the vertical direction, and
a doping profile of the back N-well decreases toward the peripheral circuit active surface from a peak of a dopant concentration of the back N-well, the peak of the dopant concentration of the back N-well being adjacent to and spaced apart from the peripheral circuit inactive surface in the vertical direction.

19. The semiconductor device of claim 18, wherein
a rate that the doping profile of the back P-well decreases toward the peripheral circuit inactive surface from the peak of the dopant concentration of the back P-well is greater than a rate that the doping profile of the back P-well decreases toward the peripheral circuit active surface from the peak of the dopant concentration of the back P-well,
a rate that the doping profile of the back N-well decreases toward the peripheral circuit inactive surface from the peak of the dopant concentration of the back N-well is greater than a rate that the doping profile of the back N-well decreases toward the peripheral circuit active surface from the peak of the dopant concentration of the back N-well, and
a value of the peak of the dopant concentration of the back P-well is greater than a value of a peak of a dopant concentration of the front P-well, and a value of the peak of the dopant concentration of the back N-well is greater than a value of a peak of a dopant concentration of the front N-well.

20. The semiconductor device of claim 18, wherein
the peripheral circuit active surface of the peripheral circuit substrate faces the cell array structure, and
the plurality of bit lines are above the plurality of channel patterns, and the plurality of capacitors are below the plurality of channel patterns.
